(19) United States
(12) Patent Application Publication
(10) Pub. No.: US 2026/0101544 A1
(43) Pub. Date: Apr. 9, 2026

(54) RADIATION-HARDENED HIGH-BREAKDOWN VOLTAGE SEMICONDUCTOR DEVICES AND METHODS OF MAKING THE SAME

(71) Applicant: Vorago Technologies, Inc., Austin, TX (US)

(72) Inventors: Patrice M. Parris, Phoenix, AZ (US); David R. Gifford, Pflugerville, TX (US)

(21) Appl. No.: 18/909,367

(22) Filed: Oct. 8, 2024

(51) Int. Cl. H01L 29/06; H01L 23/552; H01L 29/66; H01L 29/78

(52) U.S. Cl. CPC H10D 62/102; H10D 30/658; H10D 30/668; H10W 42/20; H10D 30/0289; H10D 30/0297

(57) ABSTRACT

Radiation-hardened high-breakdown voltage semiconductor devices and methods of making the same are described. An example high-breakdown voltage semiconductor device includes a source region and a drain region. The high-breakdown voltage semiconductor device further comprises an active region. The high-breakdown voltage semiconductor device further comprises a first opposite doping-type region formed within the active region towards a first distal end of the active region to separate the source region from a parasitic transistor. The high-breakdown voltage semiconductor device further comprises a second opposite doping-type region formed within the active region towards a second distal end, opposite from the first distal end, of the active region to separate the source region from a second parasitic transistor, where the source region has a first conductivity type, and where each of the first opposite doping-type region and the second opposite doping-type region has a second conductivity type, opposite of the first conductivity type.

### BACKGROUND

Semiconductor devices with a high drain to source breakdown voltage are often used for implementing high-voltage and power semiconductor devices. One example of such semiconductor devices is a laterally-diffused metal oxide semiconductor (LDMOS) device. In environments with ionizing radiation, there is an accumulation of a positive charge in the dielectric isolation regions around the transistor. This may lead to the formation of parasitic transistors along the isolation between the source region and the drain region of the LDMOS device. Because the parasitic transistors are not under the control of the transistor gate they are a source of off-state leakage current. In addition, the charge created in these regions can affect the operation and reliability of ICs. Some of the charge created along the isolation between the source region and the drain region of the LDMOS device can disrupt circuit functionality temporarily, or often, in the event of a latch-up, permanently.

Accordingly, there is a need for structures, and processes for making such structures, for eliminating the additional off-state leakage current and other degradation effects in integrated circuits as well as hardening them against the cumulative effects of radiation.

### SUMMARY

In one example, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a first opposite doping-type region formed within the active region towards a first distal end of the active region to separate the source region from a parasitic transistor. The high-breakdown voltage semiconductor device may further comprise a second opposite doping-type region formed within the active region towards a second distal end, opposite from the first distal end, of the active region to separate the source region from a second parasitic transistor, where the source region has a first conductivity type, and where each of the first opposite doping-type region and the second opposite doping-type region has a second conductivity type, opposite of the first conductivity type.

In another aspect, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a gate electrode formed within the active region, where the gate electrode region is shaped such that: (1) a first gate-controlled series transistor is formed in series with a first parasitic transistor, resulting in a first pair of series transistors formed in parallel with a first intrinsic transistor formed between the source region and the drain region, and (2) a second gate-controlled series transistor is formed in series with a second parasitic transistor, resulting in a second pair of series transistors formed in parallel with the first intrinsic transistor formed between the source region and the drain region.

In yet another aspect, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a first opposite doping-type region formed within the active region towards a first distal end of the active region to separate the source region from a first parasitic transistor. The high-breakdown voltage semiconductor device may further comprise a second opposite doping-type region formed within the active region towards a second distal end, opposite from the first distal end, of the active region to separate the source region from a second parasitic transistor, where the source region has a first conductivity type, and where each of the first opposite doping-type region and the second opposite doping-type region has a second conductivity type, opposite of the first conductivity type.

The high-breakdown voltage semiconductor device may further comprise a channel region associated with the source region and the drain region. The high-breakdown voltage semiconductor device may further comprise a first sidewall leakage improvement (SLI) region formed towards a first distal end of the channel region to increase an effective channel length of the first parasitic transistor formed in the high-breakdown voltage device relative to a channel length of a first intrinsic transistor formed in the high-breakdown voltage device. The high-breakdown voltage semiconductor device may further comprise a second sidewall leakage improvement (SLI) region formed towards a second distal end, opposite from the first distal end, of the channel region to increase an effective channel length of the second parasitic transistor formed in the high-breakdown voltage device relative to a channel length of the first intrinsic transistor formed in the high-breakdown voltage device.

In another aspect, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a gate electrode formed within the active region, where the gate electrode region is shaped such that: (1) a first gate-controlled series transistor is formed in series with a first parasitic transistor, resulting in a first pair of series transistors formed in parallel with a first intrinsic transistor formed between the source region and the drain region, and (2) a second gate-controlled series transistor formed in series with a second parasitic transistor, resulting in a second pair of series transistors formed in parallel with the first intrinsic transistor formed between the source region and the drain region. The high-breakdown voltage semiconductor device may further comprise a channel region associated with the source region and the drain region.

The high-breakdown voltage semiconductor device may further comprise a first sidewall leakage improvement (SLI) region formed towards a first distal end of the channel region to increase an effective channel length of the first parasitic transistor formed in the high-breakdown voltage device relative to a channel length of the first intrinsic transistor formed in the high-breakdown voltage device. The high-breakdown voltage semiconductor device may further comprise a second sidewall leakage improvement (SLI) region formed towards a second distal end, opposite from the first distal end, of the channel region to increase an effective channel length of the second parasitic transistor formed in the high-breakdown voltage device relative to a channel length of the first intrinsic transistor formed in the high-breakdown voltage device.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Although FIGS. 1-5 and FIGS. 9-11 show transistors with dual sources and drains, the structures and processes described herein apply equally to transistors with a single source and multiple drains, transistors with a single source and a drain pair, or a transistors with multiple sources and a single drain. Elements in the figures are illustrated for simplicity and clarity and have not necessarily been drawn to scale.

FIG. 1 shows sidewall leakage improvement regions formed in an LDMOS device in accordance with one example;

FIG. 2 shows opposite doping-type parasitic channel regions formed in an LDMOS device in accordance with one example;

FIG. 3 shows opposite doping-type parasitic channel regions formed in an LDMOS device in accordance with another example;

FIG. 4 shows a gate-controlled transistor formed in series with the parasitic channel in an LDMOS device in accordance with one example;

FIG. 5 shows total ionizing dosage (TID) improvement regions formed in an LDMOS device in accordance with one example;

FIG. 6 shows a cross-section view of TID improvement regions formed in a non-isolated LDMOS device in accordance with one example;

FIG. 7 shows a cross-section view of TID improvement regions formed in an isolated LDMOS device in accordance with one example;

FIG. 8 is a diagram of an external TID-resistant series transistor for an LDMOS device in accordance with one example;

FIG. 9 shows a combination of sidewall leakage improvement regions and opposite doping-type parasitic channel inserts formed in an LDMOS device in accordance with one example;

FIG. 10 shows a combination of sidewall leakage improvement regions and opposite doping-type parasitic channel inserts formed in an LDMOS device in accordance with another example;

FIG. 11 shows a combination of sidewall leakage improvement regions and a gate-controlled series transistor formed in an LDMOS device in accordance with one example;

FIG. 12 shows a top view of the non-isolated LDMOS device shown in FIG. 6 in accordance with one example; and

FIG. 13 shows a top view of the isolated LDMOS device shown in FIG. 7 in accordance with one example.

### DETAILED DESCRIPTION

Examples described in this disclosure relate to radiation-hardened high-breakdown voltage semiconductor devices and methods of making the same. As used herein the term “high-breakdown voltage” includes a range of voltages between 5 volts to 1500 volts. The high-breakdown voltage may refer to the drain to source voltage of a semiconductor devices, such as a laterally-diffused metal oxide semiconductor (LDMOS) device. Such LDMOS devices may be included as part of various types of integrated circuits. Integrated circuits include but are not limited to Field-Programmable Gate Arrays (FPGAs), Application-Specific Integrated Circuits (ASICs), Application-Specific Standard Products (ASSPs), System-on-a-Chip systems (SoCs), Complex Programmable Logic Devices (CPLDs), Digital-Signal Processors (DSPs), controllers (e.g., automotive controllers, communication controllers, IoT controllers), sensors, image sensors, or other types of integrated circuits.

In environments with ionizing radiation, positive charge accumulates in the dielectric isolation regions along the edges of active region. This can lead to the formation of a parasitic transistor between the source and the drain of the device. Because such a parasitic transistor is not controlled by the gate associated with the device, it is a source of off-state leakage current. In addition, the charge created in these regions can affect the operation and reliability of ICs. Some of the charge created along the isolation between the source region and the drain region of the high-breakdown voltage semiconductor device (e.g., an LDMOS device) can disrupt circuit functionality.

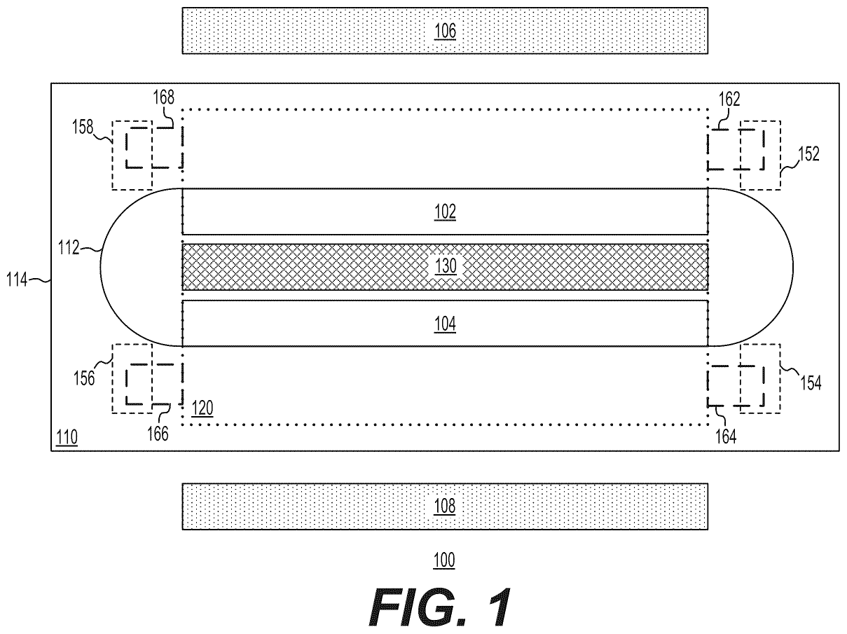

FIG. 1 shows sidewall leakage improvement (SLI) regions formed in an LDMOS device 100 in accordance with one example. To illustrate the structure and the functionality of the SLI regions, certain portions of LDMOS device 100 are emphasized. A complete LDMOS device may include contacts and other structures for operation that are not shown in FIG. 1. The use of the SLI regions formed in LDMOS device 100, however, is not limited to a particular implementation of the LDMOS. In addition, the SLI regions described herein can be used with other high-voltage device designs, including vertical double-diffused metal-oxide semiconductor (VDMOS) devices or trench metal-oxide semiconductor (TMOS) devices.

In this example, LDMOS device 100 is formed in a P-type substrate and includes two source regions and two drain regions with optional associated drain extension regions. The drain extension regions may be formed by implanting n-type dopants, such as phosphorous, arsenic, antimony, bismuth, or lithium into the P-type substrate. Thus, in this example, LDMOS device 100 includes a source region 102 and another source region 104. Each of source regions 102 and 104 are implemented as N+ type regions in this example. LDMOS device 100 further includes a drain region 106 and another drain region 108. Each of drain regions 106 and 108 are also implemented as N+ type regions in this example. LDMOS device 100 further includes a gate electrode 110, whose inner edge is indicated by reference number 112 and whose outer edge is indicated by reference number 114. Within the enclosure formed by the inner edge of the gate electrode, a body contact 130 is formed. In this example, body contact 130 is a P+ type body contact. As an example, the P+ type body contact may have a doping concentration of 1×10²⁰ atoms per cm³ and the P− type substrate may have a doping concentration of 1×10¹⁶ atoms per cm³. The atoms may correspond to boron or another p-type implant material. LDMOS device 100 is implemented such that the top view of the LDMOS shown in FIG. 1 looks like a racetrack.

With continued reference to FIG. 1, LDMOS device 100 further includes an active region 120, which may correspond to the region between the dielectric isolation regions (e.g., shallow-trench isolation (STI) regions) (not shown). In environments with ionizing radiation, positive charge accumulates in the dielectric isolation regions along the edges of active region 120. This can lead to the formation of a parasitic transistor between the source and the drain of the device. As an example, a parasitic transistor may be formed between source region 102 and drain region 106. Another parasitic transistor may be formed between source region 104 and drain region 108. Because such parasitic transistors are not under the control of the gate associated with the device, they are a source of off-state leakage current.

To eliminate, or delay, the formation of such parasitic transistors, during the formation of the LDMOS device, implants 152, 154, 156, and 158 are performed. Implants 152, 154, 156, and 158 are performed using an additional mask during the formation of LDMOS device 100. In addition, sidewall leakage improvement (SLI) regions 162, 164, 166, and 168 are formed. SLI regions 162, 164, 166, and 168 may be formed using an oxide definition (OD) mask, which is used for channel stop definition and local oxidation of silicon (LOCOS), shallow trench isolation (STI), or another form of isolation. Alternatively, SLI regions 162, 164, 166, and 168 may be formed as part of the formation of active region 120 using the same mask that is used to form active region 120. Implants 152, 154, 156, and 158 are formed such that they cover as much area of the SLI regions 162, 164, 166, and 168 without impinging upon the channel area of LDMOS device 100. In a case where the shape of SLI regions 162, 164, 166, and 168 extends beyond the gate electrode (or the gate electrode is appropriately shaped), the P+-type source/drain implants may be used to form implants 152, 154, 156, and 158.

Still referring to FIG. 1, SLI regions 162, 164, 166, and 168 by themselves increase the apparent channel length of the parasitic transistor. In other words, SLI regions 162, 164, 166, and 168 are effectively lateral extensions of the channel region located between the source and drain regions. Without the SLI regions 162, 164, 166, and 168, any parasitic transistors formed in LDMOS device 100 because of the ionization have the same channel length as the intrinsic transistor. With the SLI regions 162, 164, 166, and 168, the effective channel length of the parasitic transistors is greater than the intrinsic transistor channel length. As described in the present disclosure, the term “intrinsic transistor” refers to the MOS transistor formed within the LDMOS device as opposed to the parasitic sidewall MOS transistor formed within the LDMOS device.

Implants 152, 154, 156, and 158 further improve the total ionizing dose (TID) performance of the transistor by raising the threshold voltage of any parasitic transistors that may form in LDMOS device 100. Raising the threshold voltage increases the amount of charge which needs to accumulate in the dielectric in order to invert the silicon adjacent to the isolation and form the parasitic transistor. In one example, SLI regions 162, 164, 166, and 168 may be used without implants 152, 154, 156, and 158. In addition, because only a small fraction of the on-state channel current for LDMOS device 100 flows through the lateral extension, the device's DC and low-frequency simulated models (e.g., SPICE models) are not significantly perturbed. However, there may be a minor increase in the gate-to-body capacitance, which may decrease the switching speed of the LDMOS transistor.

Implants 152, 154, 156, and 158 and SLI regions 162, 164, 166, and 168 can be formed regardless of whether LDMOS device 100 is fabricated in bulk silicon, silicon films, such as silicon-on-insulator (SOI) substrates, or other semiconductor material. In the case of an SOI substrate, a p-type semiconductor layer may be formed in the SOI substrate. Although FIG. 1 shows a specific configuration of implants 152, 154, 156, and 158 and SLI regions 162, 164, 166, and 168 in terms of their location and shape, the implants and the SLI regions may be formed in additional, or alternative, locations and may have different shapes than shown in FIG. 1. In addition, although FIG. 1 shows drain regions 106 and 108 formed outside of active region 120 and source regions 102 and 104 formed inside active region 120, the arrangement could be reversed, such that drain regions 106 and 108 are formed inside an altered active region 120 and source regions 102 and 104 are formed in other active regions outside of active region 120. In addition, although body contact 130 is shown as physically formed in the same active region as the source regions 102 and 104, body contact 130 may be contained in a different active region from one or both of source regions 102 and 104.

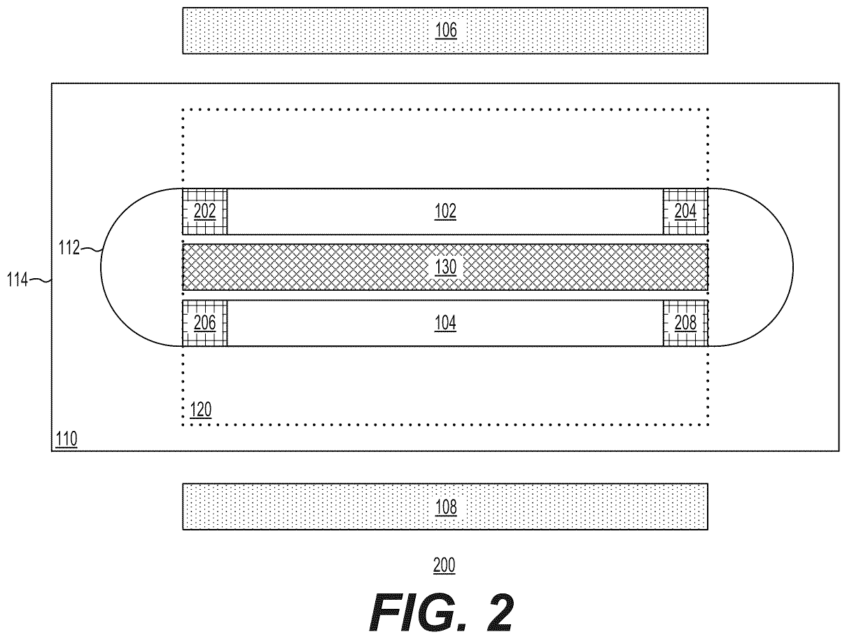

FIG. 2 shows opposite doping-type parasitic channel regions formed in an LDMOS device 200 in accordance with one example. LDMOS device 200, like LDMOS device 100, is formed in a P-type substrate and includes two source regions and two drain regions with optional associated drain extension regions. The drain extension regions may be formed by implanting n-type dopants, such as phosphorous, arsenic, antimony, bismuth, or lithium into the P-type substrate. The same or similar regions or structures that are shown in FIG. 2 are referred to using the same or similar reference numbers as used in FIG. 1. Thus, in this example, LDMOS device 200 includes a source region 102 and another source region 104. Each of source regions 102 and 104 are N+ type regions in this example. LDMOS device 200 further includes a drain region 106 and another drain region 108. Each of drain regions 106 and 108 are N+ type regions in this example. LDMOS device 200 further includes a gate electrode 110, whose inner edge is indicated by reference number 112 and whose outer edge is indicated by reference number 114. Within the enclosure formed by the inner edge of the gate electrode, a body contact 130 is formed. In this example, body contact 130 is a P+ type body contact. As an example, the P+ type body contact may have a doping concentration of 1×10²⁰ atoms per cm³ and the P− type substrate may have a doping concentration of 1×10¹⁶ atoms per cm³. The atoms may correspond to boron or another p-type implant material. LDMOS device 200 is implemented such that the top view of the LDMOS shown in FIG. 2 looks like a racetrack.

With continued reference to FIG. 2, LDMOS device 200 further includes an active region 120, which may correspond to the region between the dielectric isolation regions (e.g., shallow-trench isolation (STI) regions) (not shown). As explained earlier, in environments with ionizing radiation, positive charge accumulates in the dielectric isolation regions along the edges of active region 120. This can lead to the formation of a parasitic transistor between the source and the drain of the device. As an example, a parasitic transistor may be formed between source region 102 and drain region 106. Another parasitic transistor may be formed between source region 104 and drain region 108.

With continued reference to FIG. 2, opposite doping-type channel regions 202, 204, 206, and 208 are formed as part of LDMOS device 200. In this example, the opposite doping-type channel regions 202, 204, 206, and 208 are formed using a P-type implant to separate the LDMOS source regions (e.g., source regions 102 and 104) from any parasitic transistors that may form in LDMOS device 200. Each of the opposite doping-type channel regions 202, 204, 206, and 208 creates a junction which isolates the source of the intrinsic transistor, which also acts as the source of the parasitic transistor, from the channel of the parasitic transistor. This makes it significantly more difficult for the parasitic transistor to form. In alternative embodiments, opposite doping-type channel regions 202, 204, 206 and 208 may be electrically shorted (i) to body contact 130 and/or one or both of source regions 102 and 104, (ii) to only some portion of body contact 130 and source regions 102 and 104, or (iii) to none of body contact 130 and source regions 102 and 104. For the same width of the active region, the effective width of the LDMOS transistor is decreased by the opposite doping-type channel regions 202, 204, 206, and 208.

Opposite doping-type channel regions 202, 204, 206, and 208 can be formed regardless of whether LDMOS device 200 is fabricated in bulk silicon, silicon films, such as silicon-on-insulator (SOI) substrates, or other semiconductor material. In the case of an SOI substrate, a p-type semiconductor layer may be formed in the SOI substrate. Although FIG. 2 shows a specific configuration of opposite doping-type channel regions 202, 204, 206, and 208 in terms of their location and shape, they may be formed in additional, or alternative, locations and may have different shapes than shown in FIG. 2. In addition, although FIG. 2 shows drain regions 106 and 108 formed outside of active region 120 and source regions 102 and 104 formed inside active region 120, the arrangement could be reversed, such that drain regions 106 and 108 are formed inside active region 120 and source regions 102 and 104 are formed outside of active region 120. In addition, although body contact 130 is shown as physically formed in the same active region as the source regions 102 and 104, body contact 130 may be contained in a different active region from one or both of source regions 102 and 104.

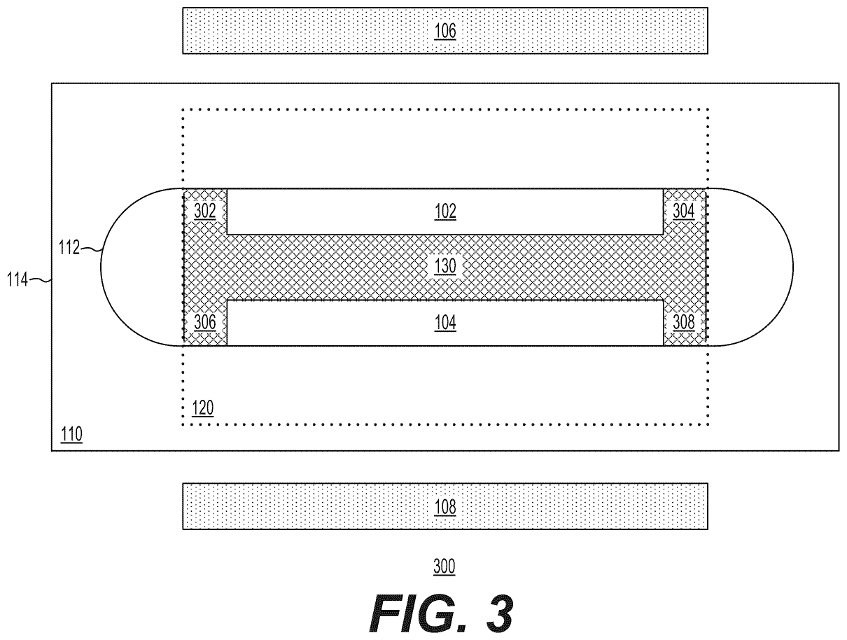

FIG. 3 shows opposite doping-type parasitic channel regions formed in an LDMOS device 300 in accordance with another example. Unlike LDMOS device 200, the need for an additional mask can be eliminated by using the P+ body implant itself to form the opposite doping-type parasitic channel regions as shown in FIG. 3. LDMOS device 300, like LDMOS device 100, may be formed in a P-type substrate and includes two source regions and two drain regions with optional associated drain extension regions. The drain extension regions may be formed by implanting n-type dopants, such as phosphorous, arsenic, antimony, bismuth, or lithium into the P-type substrate. The same or similar regions or structures that are shown in FIG. 3 are referred to using the same or similar reference numbers as used in FIG. 1. Thus, in this example, LDMOS device 300 includes a source region 102 and another source region 104. Each of source regions 102 and 104 are N+ type regions in this example. LDMOS device 300 further includes a drain region 106 and another drain region 108. Each of drain regions 106 and 108 are N+ type regions in this example.

LDMOS device 300 further includes a gate electrode 110, whose inner edge is indicated by reference number 112 and whose outer edge is indicated by reference number 114. LDMOS device 300 further includes an active region 120, which may correspond to the region between the dielectric isolation regions (e.g., shallow-trench isolation (STI) regions) (not shown). As explained earlier, in environments with ionizing radiation, positive charge accumulates in the dielectric isolation regions along the edges of active region 120. This can lead to the formation of a parasitic transistor between the source and the drain of the device. As an example, a parasitic transistor may be formed between source region 102 and drain region 106. Another parasitic transistor may be formed between source region 104 and drain region 108.

With continued reference to FIG. 3, within the enclosure formed by the inner edge of gate electrode 110 a body contact 130 is formed. In this example, body contact 130 is a P+ type body contact. Using the same implant for forming body contact 130, opposite doping-type channel regions 302, 304, 306, and 308 are formed as part of LDMOS device 300. As an example, the P+ type body contact and the opposite doping-type channel regions 302, 304, 306, and 308 may have a doping concentration of 1×10²⁰ atoms per cm³ and the P− type substrate may have a doping concentration of 1×10¹⁶ atoms per cm³. The atoms may correspond to boron or another p-type implant material. In this example, the opposite doping-type channel regions 302, 304, 306, and 308 are formed to separate the LDMOS source regions (e.g., source regions 102 and 104) from any parasitic transistors that may form in LDMOS device 300. Each of the opposite doping-type channel regions 302, 304, 306, and 308 creates a junction which isolates the source of the intrinsic transistor, which also acts as the source of the parasitic transistor, from the channel of the parasitic transistor. This makes it significantly more difficult for the parasitic transistor to form. In alternative embodiments, opposite doping-type channel regions 302, 304, 306 and 308 may be electrically shorted (i) to body contact 130 and/or one or both of source regions 102 and 104, (ii) to only some portion of body contact 130 and source regions 102 and 104, or (iii) to none of body contact 130 and source regions 102 and 104. For the same width of the active region, the effective width of the LDMOS transistor is decreased by the opposite doping-type channel regions 302, 304, 306, and 308.

Opposite doping-type channel regions 302, 304, 306, and 308 can be formed regardless of whether LDMOS device 300 is fabricated in bulk silicon, silicon films, such as silicon-on-insulator (SOI) substrates, or other semiconductor material. In the case of an SOI substrate, a p-type semiconductor layer may be formed in the SOI substrate. Although FIG. 3 shows a specific configuration of opposite doping-type channel regions 302, 304, 306, and 308 in terms of their location and shape, they may be formed in additional, or alternative, locations and may have different shapes than shown in FIG. 3. In addition, although FIG. 3 shows drain regions 106 and 108 formed outside of active region 120 and source regions 102 and 104 formed inside active region 120, the arrangement could be reversed, such that drain regions 106 and 108 are formed inside an altered active region 120 and source regions 102 and 104 are formed in other active regions outside of active region 120. In addition, as described earlier with respect to FIGS. 1 and 2, body contact 130 can be formed physically separated from source regions 102 and 104. Even when body contact 130 is physically separated from source regions 102 and 104, opposite doping-type regions 302, 304, 306 and 308 can be formed with the same implant as body contact 130.

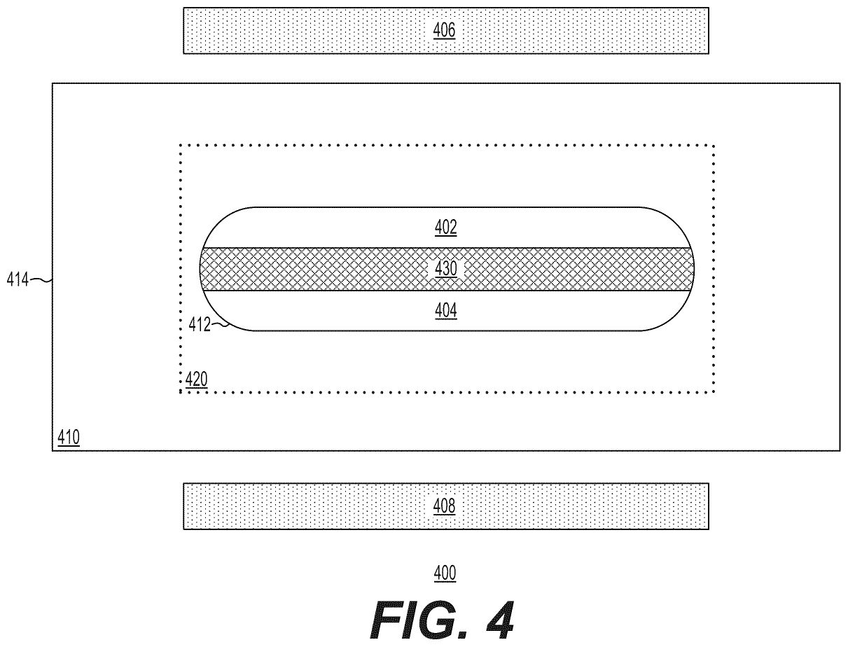

FIG. 4 shows a gate-controlled transistor formed in series with the parasitic channel in an LDMOS device 400 in accordance with one example. This example relates to an alternative way of separating the source regions of the LDMOS transistor from the accumulated charge in the isolation by using the gate material. LDMOS device 400, like LDMOS device 100, can be formed in a P-type substrate and includes two source regions and two drain regions with optional associated drain extension regions. The drain extension regions may be formed by implanting n-type dopants, such as phosphorous, arsenic, antimony, bismuth, or lithium into the P-type substrate. The same or similar regions or structures that are shown in FIG. 4 are referred to using the same or similar reference numbers as used in FIG. 1. In this example, LDMOS device 400 includes a source region 402 and another source region 404. Each of source regions 402 and 404 are N+ type regions in this example.

LDMOS device 400 further includes a drain region 406 and another drain region 408. Each of drain regions 406 and 408 are N+ type regions in this example. LDMOS device 400 further includes a gate electrode 410, whose inner edge is indicated by reference number 412 and whose outer edge is indicated by reference number 414. Within the enclosure formed by the inner edge of gate electrode a body contact 430 is formed.

With continued reference to FIG. 4, LDMOS device 400 further includes an active region 420, which may correspond to the region between the dielectric isolation regions (e.g., shallow-trench isolation (STI) regions) (not shown). As explained earlier, in environments with ionizing radiation, positive charge accumulates in the dielectric isolation regions along the edges of active region 420. This can lead to the formation of a parasitic transistor between the source and the drain of the device. As an example, a parasitic transistor may be formed between source region 402 and drain region 406. Another parasitic transistor may be formed between source region 404 and drain region 408.

With continued reference to FIG. 4, in this example, unlike source regions 102 and 104 of FIG. 1, source regions 402 and 404 are formed such that the gate material between the inner edge (reference number 412) of gate electrode 410 separates the N+ source regions 402 and 404 from the parasitic channel (e.g., formed because of the accumulation of the positive charge in the dielectric isolation regions along the edges of active region). As a result, the leakage path between the source (e.g., source region 402) and the drain (e.g., drain region 406) now consists of two transistors in series—a gate-controlled MOSFET and the parasitic transistor. Since one of these transistors is under the control of the gate electrode, as long as its channel length is greater than the intrinsic transistor channel length, it will be switched off when the intrinsic transistor is switched off, and, therefore, limit the total leakage current through the parasitic transistor. Additionally, this gate-controlled transistor can have a shorter channel length than the intrinsic transistor if the targeted TID leakage specification allows it.

Notably, this limiting mechanism further improves the total ionizing dose (TID) performance of the LDMOS transistor. Since TID performance is improved by simply re-shaping the gate electrode, this solution may not need any additional masking steps over the existing process. For the same width of the active region 420 of LDMOS device 400, the effective width of the LDMOS transistor is decreased by the shape of gate electrode 410. Thus, the simulated model (e.g., a SPICE model) for an LDMOS with the gate-controlled transistor in series with the parasitic channel may differ from that of an otherwise-identical LDMOS without the gate-controlled transistor in series with the parasitic channel. In addition, the increased gate-to-body capacitance may result in lower switching speeds for the LDMOS transistor.

The gate-controlled transistor, in series with the parasitic channel, can be formed regardless of whether LDMOS device 400 is fabricated in bulk silicon, silicon films, such as silicon-on-insulator (SOI) substrates, or other semiconductor material. In the case of an SOI substrate, a p-type semiconductor layer may be formed in the SOI substrate. Although FIG. 4 shows a specific configuration of the gate electrode 410 and source regions 402 and 404 in terms of their location and shape, they may be formed in additional, or alternative, locations and may have different shapes than shown in FIG. 4. In addition, although FIG. 4 shows drain regions 406 and 408 formed outside of active region 120 and source regions 402 and 404 formed inside active region 420, the arrangement could be reversed, such that drain regions 406 and 408 could be combined within a central active region and source regions 402 and 404 could be formed on either side of the central active region. In addition, although body contact 430 is shown as physically formed in the same active region as the source regions 402 and 404, body contact 430 may be contained in a different active region from one or both of source regions 402 and 404.

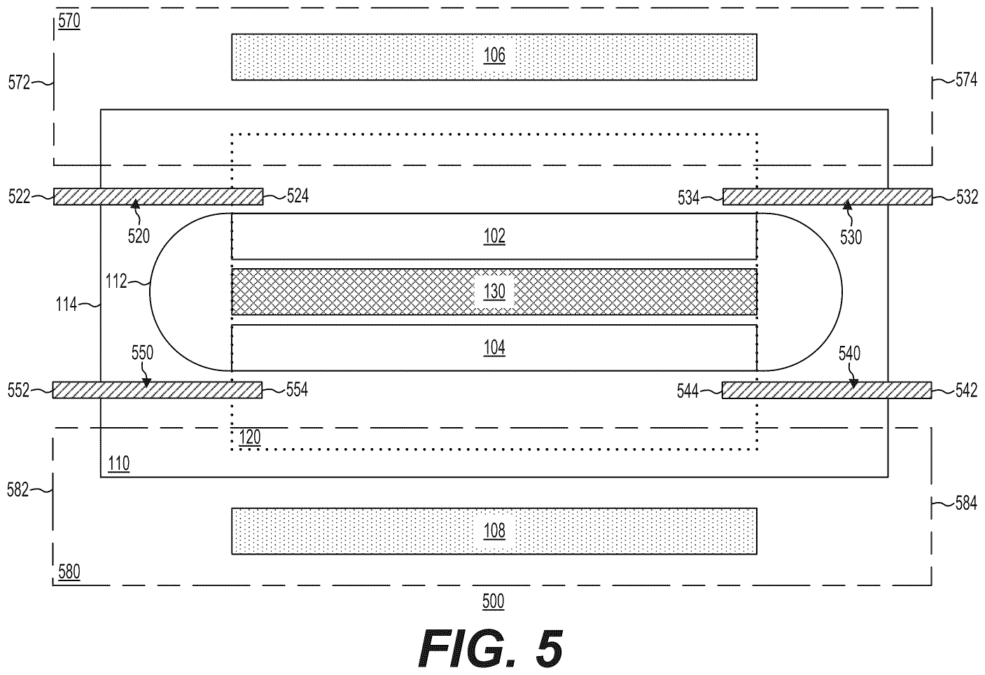

FIG. 5 shows total ionizing dosage (TID) improvement regions formed in an LDMOS device 500 in accordance with one example. The TID performance of the LDMOS transistor can also be improved by using implantation to boost the threshold voltage of the parasitic transistor in at least a portion of the intrinsic transistor channel. LDMOS device 500, like LDMOS device 100, is formed in a P-type substrate and includes two source regions and two drain regions with optional drain extension regions. The drain extension regions may be formed by implanting n-type dopants, such as phosphorous, arsenic, antimony, bismuth, or lithium into the P-type substrate. The same or similar regions or structures that are shown in FIG. 5 are referred to using the same or similar reference numbers as used in FIG. 1. Thus, in this example, LDMOS device 500 includes a source region 102 and another source region 104. Each of source regions 102 and 104 are N+ type regions in this example. LDMOS device 500 further includes a drain region 106 and another drain region 108. Each of drain regions 106 and 108 are N+ type regions in this example. LDMOS device 500 is further shown as including drain extension regions 570 and 580, which are not shown in FIGS. 1-4; although the LDMOS devices shown in these figures can include such regions.

LDMOS device 500 further includes a gate electrode 110, whose inner edge is indicated by reference number 112 and whose outer edge is indicated by reference number 114. Within the enclosure formed by the inner edge of gate electrode a body contact 130 is formed. In this example, body contact 130 is a P+ type body contact. LDMOS device 500 is implemented such that the top view of the LDMOS shown in FIG. 5 looks like a racetrack.

With continued reference to FIG. 5, LDMOS device 500 further includes an active region 120, which may correspond to the region between the dielectric isolation regions (e.g., shallow-trench isolation (STI) regions) (not shown). As explained earlier, in environments with ionizing radiation, positive charge accumulates in the dielectric isolation regions along the edges of active region 120. This can lead to the formation of a parasitic transistor between the source and the drain of the device. As an example, a parasitic transistor may be formed between source region 102 and drain region 106. Another parasitic transistor may be formed between source region 104 and drain region 108.

The TID performance of the LDMOS transistor can also be improved by using implantation to boost the threshold voltage of the parasitic transistor in at least a portion of the intrinsic transistor channel. LDMOS device 500 is shown with four TID improvement regions 520, 530, 540, and 550. In this example, although TID improvement regions 520, 530, 540, and 550 are shown as being extended to the lateral ends of the drain extension regions (e.g., lateral ends 572 and 574 of drain extension region 570 and lateral ends 582 and 584 of drain extension region 580), they need not extend all the way to the lateral ends, or alternatively, extend beyond the lateral ends. Thus, in this example, TID improvement region 520 has a left edge 522 that extends as far as a left edge 572 of drain extension region 570. TID improvement region 530 has a right edge 532 that extends as far as a right edge 574 of drain extension region 570. TID improvement region 540 has a right edge 542 that extends as far as a right edge 584 of drain extension region 580. TID improvement region 550 has a left edge 552 that extends as far as a left edge 582 of drain extension region 580.

In this example, each of the TID improvement regions only need to be extended beyond gate electrode 110 far enough to create a sufficiently long effective channel length for the charge flowing around them between a respective source (e.g., source 102) and a respective drain (e.g., drain 106). In FIG. 5, the extent to which TID improvement region 520 extends is the distance between edge 522 of TID improvement region 520 and the outer edge 114 of gate electrode 110. The extent to which TID improvement region 530 extends is the distance between edge 532 of TID improvement region 530 and the outer edge 114 of gate electrode 110. The extent to which TID improvement region 540 extends is the distance between edge 542 of TID improvement region 540 and the outer edge 114 of gate electrode 110. The extent to which TID improvement region 550 extends is the distance between edge 552 of TID improvement region 550 and the outer edge 114 of gate electrode 110.

Moreover, in this example, the extent of the overlap into the channel is also determined by the desired TID performance. In FIG. 5, the extent to which TID improvement region 520 overlaps with the channel is the distance between edge 524 of TID improvement region 520 and the outer edge of active region 120. The extent to which TID improvement region 530 overlaps with the channel is the distance between edge 534 of TID improvement region 530 and the outer edge of active region 120. The extent to which TID improvement region 540 overlaps with the channel is the distance between edge 544 of TID improvement region 540 and the outer edge of active region 120. The extent to which TID improvement region 550 overlaps with the channel is the distance between edge 554 of TID improvement region 550 and the outer edge of active region 120. Decreasing or eliminating the overlap can result in a narrow “low-Vt” parasitic transistor, while increasing the overlap removes the ‘low-Vt’ region but may decrease the LDMOS transconductance and increase the gate-to-body capacitance of the LDMOS transistor, resulting in slower switching speeds. The exact extent of the TID improvement implant within the length of the intrinsic device channel will depend on the breakdown voltage requirements of the intended applications and the breakdown voltage of the LDMOS device without the TID Improvement implant. In general, the higher the breakdown voltage of the LDMOS device, the farther the TID improvement implant will need to be from the drain extension regions 570 and 580. In most process flows, the TID improvement implant may need its own mask, adding one mask to the flow.

TID improvement regions 520, 530, 540, and 550 can be formed regardless of whether LDMOS device 500 is fabricated in bulk silicon, silicon films, such as silicon-on-insulator (SOI) substrates, or other semiconductor material. In the case of an SOI substrate, a p-type semiconductor layer may be formed in the SOI substrate. Although FIG. 5 shows a specific configuration of TID improvement regions 520, 530, 540, and 550 in terms of their location and shape, they may be formed in additional, or alternative, locations and may have different shapes than shown in FIG. 5. In addition, although FIG. 5 shows drain regions 106 and 108 formed outside of active region 120 and source regions 102 and 104 formed inside active region 120, the arrangement could be reversed, such that drain regions 106 and 108 are formed inside an altered active region 120 and source regions 102 and 104 are formed in different active regions outside of active region 120. In addition, although body contact 130 is shown as physically formed in the same active region as the source regions 102 and 104, body contact 130 may be contained in a different active region from one or both of source regions 102 and 104.

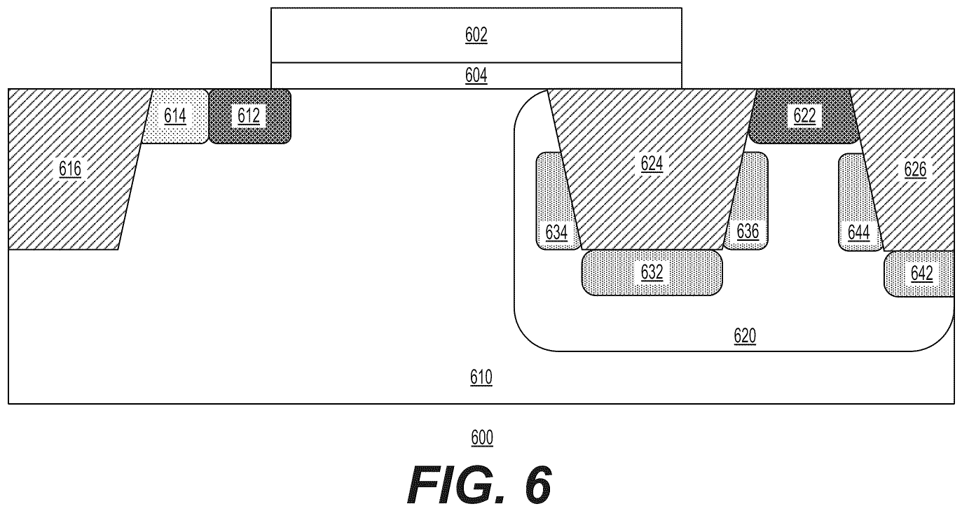

FIG. 6 shows a cross-section view of the TID improvement regions formed in a non-isolated LDMOS device 600 in accordance with one example. Non-isolated LDMOS device 600 does not include an isolating N-well. LDMOS device 600 includes a gate electrode 602 and a gate oxide layer 604. LDMOS device 600 includes a P-type substrate 610. P-type substrate 610 may be a single crystal body or a p-type epilayer. An N-type drift drain extension region 620, extending partially under gate electrode 602, is formed in P-type substrate 610. N-type drift drain extension region 620 may be formed by implanting n-type dopants, such as phosphorous, arsenic, antimony, bismuth, or lithium into the P− type substrate. Although not shown in FIG. 6, source 612 and body contact 614 can optionally be separated by an isolation region. LDMOS device 600 further includes a source (N+ type in this example) 612 and a body contact (P+ type in this example) 614. LDMOS device 600 is further shown with an isolation region 616. LDMOS device 600 further includes a drain (N+ type in this example) 622. Drain 622 is formed within N-type drift region 620. LDMOS device 600 further includes isolation regions 624 and 626. Isolation regions 616, 624, and 626 may be formed by depositing insulating material and selectively removing portions of the insulating material. Insulating materials such as silicon dioxide, silicon nitride, or other similar insulation materials may be used. In one example, the isolation regions may be configured as shallow trench isolation (STI) structures. Instead of STI, local oxidation of silicon (LOCOS) or other means of isolation may also be used.

With continued reference to FIG. 6, TID improvement region 632 is formed below isolation region 624 within the N-type drift region 620. TID improvement region 642 is formed below isolation region 626 within the N-type drift region 620. Additional TID improvement regions can be formed adjacent to the sidewalls of isolation regions 624 and 626. Thus, in this example, TID improvement region 634 is formed along one sidewall of isolation region 624 and another TID improvement region 636 is formed along the other sidewall of isolation region 624. In addition, TID improvement regions 642 and 644 are optionally formed beneath and along one sidewall of isolation region 626. In this example, TID improvement regions are formed such that they are wrapped around both the sidewalls and the bottom of the isolation region. Although not shown in FIG. 6, additional or alternative TID improvement regions may be formed as part of LDMOS device 600. As an example, another TID improvement region similar to TID improvement regions 632 and 642 can be formed below isolation region 616. The TID improvement regions shown in FIG. 6 increase the total integrated dose (TID) for the LDMOS device and the integrated circuit. As the integrated circuit is bombarded by energetic particles, these particles create electron-hole pairs in the dielectric regions of the integrated circuit. A certain fraction of the electron-hole pairs can get trapped in the dielectric. The movement of the holes through the dielectric can also release hydrogen ions, which can themselves create interface states that further enhance charge trapping in the dielectric regions of the integrated circuit. Eventually, when enough positive charge has been trapped in the dielectric, accumulation layers are formed in the silicon surface. The accumulation layers lead to deterioration of the device performance, including providing leakage paths for an increased amount of current between N+ source and drain regions. As the integrated dose increases, so do the amount of the trapped charge, the degree of accumulation, and the leakage current until the leakage current exceeds that specified for the device's contribution to the integrated circuit (IC). The TID improvement regions eliminate or decrease the degree of accumulation and the leakage current in those areas for any integrated dose and thereby allow the IC to remain functional to the higher total integrated dose.

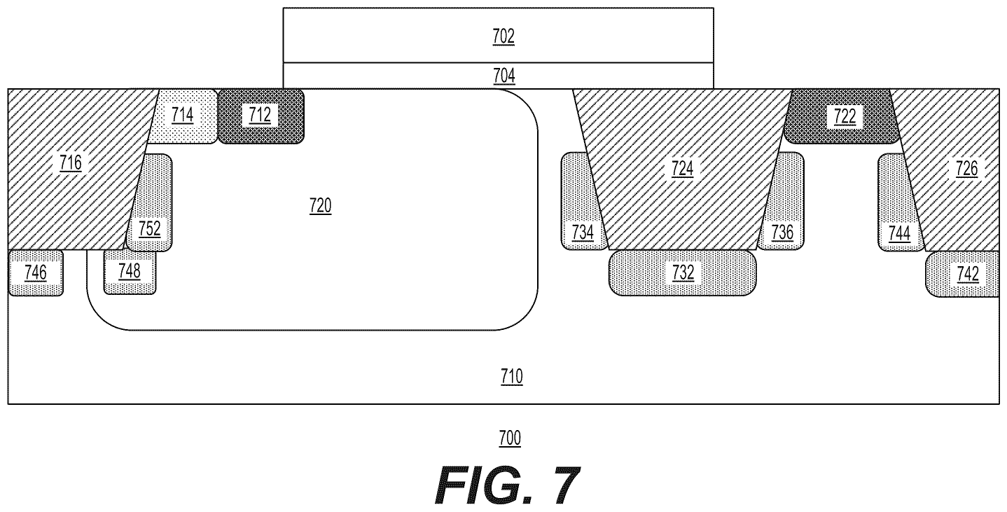

FIG. 7 shows a cross-section view of TID improvement regions formed in an isolated LDMOS device 700 in accordance with one example. Isolated LDMOS device 700 includes an isolating N-well 710. Isolating N-well 710 may be formed by implanting n-type dopants, such as phosphorous, arsenic, antimony, bismuth, or lithium into the P-type substrate. LDMOS device 700 includes a gate electrode 702 and a gate oxide layer 704. LDMOS device 700 includes a P-type substrate (not shown), which, for example, may be a single-crystal body or a p-type epilayer. A P-type body region 720 is formed within isolating N-well 710. LDMOS device 700 further includes a source (N+ type in this example) 712 and a body contact (P+ type in this example) 714. Although not shown in FIG. 7, source 712 and body contact 714 can optionally be separated by an isolation region. LDMOS device 700 is further shown with an isolation region 716. LDMOS device 700 further includes a drain (N+ type in this example) 722. Drain 722 is formed within isolating N-well 710. LDMOS device 700 further includes isolation regions 724 and 726. Isolation regions 716, 724, and 726 may be formed by depositing insulating material and selectively removing portions of the insulating material. Insulating materials such as silicon dioxide, silicon nitride, or other similar insulation materials may be used. In one example, the isolation regions may be configured as shallow trench isolation (STI) structures. Instead of STI, local oxidation of silicon (LOCOS) or other means of isolation may also be used.

With continued reference to FIG. 7, TID improvement region 732 is formed below isolation region 724 within the isolating N-well 710. TID improvement region 742 is formed below isolation region 726 within isolating N-well 710. Additional TID improvement regions can be formed adjacent to the sidewalls of isolation regions 724 and 726. Thus, in this example, TID improvement region 734 is formed along one sidewall of isolation region 724 and another TID improvement region 736 is formed along the other sidewall of isolation region 724. In addition, TID improvement regions 742 and 744 are optionally formed beneath and along one sidewall of isolation region 726. In this example, TID improvement regions are formed such that they are wrapped around both the sidewalls and the bottom of the isolation region. Another optional TID improvement region 718 is shown as formed below isolation region 716. Although not shown in FIG. 7, additional or alternative TID improvement regions may be formed as part of LDMOS device 700. The TID improvement regions shown in FIG. 7 increase the total integrated dose (TID) for the LDMOS device and the integrated circuit. As the integrated circuit is bombarded by energetic particles, these particles create electron-hole pairs in the dielectric regions of the integrated circuit. A certain fraction of the electron-hole pairs can get trapped in the dielectric. The movement of the holes through the dielectric can also release hydrogen ions, which can themselves create interface states that further enhance charge trapping in the dielectric regions of the integrated circuit. Eventually, when enough positive charge has been trapped in the dielectric, accumulation layers are formed in the silicon surface. The accumulation layers can degrade device performance, including by providing leakage paths for an increased amount of current between N+ source and drain regions. As the integrated dose increases, so do the amount of the trapped charge, the degree of inversion, and the leakage current until the leakage current exceeds that specified for the device's contribution to the integrated circuit (IC). The TID improvement regions eliminate or decrease the degree of accumulation and the leakage current in those areas for any integrated dose and thereby allow the IC to remain functional to the higher total integrated dose.

As explained earlier with respect to FIG. 4, the leakage path between the source (e.g., source region 402 of FIG. 4) and the drain (e.g., drain region 406 of FIG. 4) can be modified such that it consists of two transistors in series—a gate-controlled MOSFET and the parasitic transistor. As noted above, since one of these transistors is under the control of the gate electrode, as long as its channel length is greater than the intrinsic transistor channel length, it will be switched off when the intrinsic transistor is switched off, and, therefore, limit the total leakage current through the parasitic transistor. Additionally, this gate-controlled transistor can have a shorter channel length than the intrinsic transistor if the targeted TID leakage specification allows it.

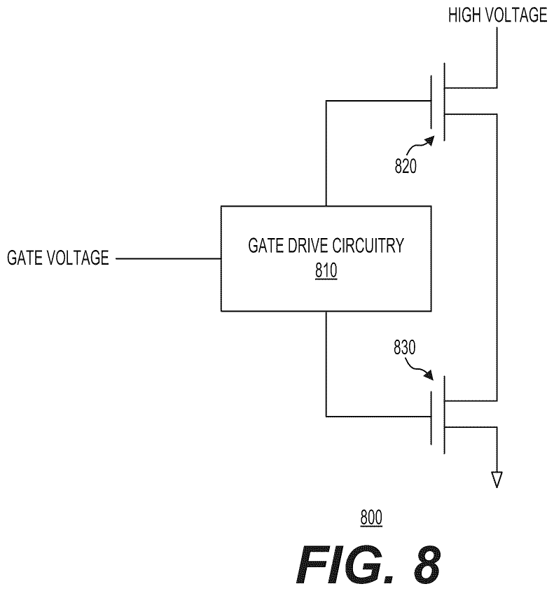

Thus, this limiting mechanism further improves the total ionizing dose (TID) performance of the LDMOS transistor. This idea of increasing the TID robustness using the transistor in series as shown in FIG. 4 can also be implemented by arranging in series another transistor external to the LDMOS device. FIG. 8 is a diagram of a circuit 800 that has an external transistor 830 in series with an LDMOS transistor 820 for an LDMOS device (or another high-voltage device) in accordance with one example. As part of circuit 800, the common gate voltage is coupled via gate drive circuitry 810 to the respective gates of both LDMOS transistor 820 and external transistor 830. The gates of transistors 820 and 830 could also be biased separately. Since both LDMOS transistor 820 and external transistor 830 would be exposed to radiation simultaneously, to maximize the TID performance of the pair, the external transistor 830 (arranged in series with LDMOS transistor 820) will need to be TID-resistant in order to present a barrier to TID-induced leakage in the LDMOS transistor 820. Transistor 830 can be made TID-resistant through various means, including the addition of appropriately engineered implants to the transistor. To reduce processing cost, some or all of the implants used in forming the TID improvement regions 632, 634, 636, 642 and 644 in FIG. 6 and 732, 734, 736, 742 and 744 in FIG. 7 can be used to make transistor 830 resistant to TID degradation.

In this example, to minimize (or reduce) the resistance penalty of external transistor 830, the transistor type with the highest conductivity should be used. In most technology nodes, this will be one of the available low-voltage (LV) transistor types which cannot sustain the same gate voltage as the high-voltage transistor. Therefore, there is a trade-off between minimizing the conductivity loss (e.g., associated with a thicker gate oxide) for a low-voltage transistor and the ease of design associated with gate drive circuitry 810 for use with a low-voltage transistor having the same gate oxide thickness as the high-voltage transistor. In general, low-voltage transistors need to be protected from the high drain voltages that the high-voltage transistors experience; and, so, such low-voltage transistors should be used on the low side of the combination, as shown in FIG. 8.

Similar to transistor 830, other low-voltage transistors in the IC need to be made TID-resistant in order for the entire IC to meet its TID specifications. Different means, including the addition of appropriately engineered implants to the transistor, can be used. As with transistor 830, the cost of fabricating the IC can be reduced by re-using some or all of the implants used in forming the TID improvement regions 632, 634, 636, 642 and 644 in FIG. 6 and 732, 734, 736, 742 and 744 in FIG. 7 to harden these transistors against TID degradation.

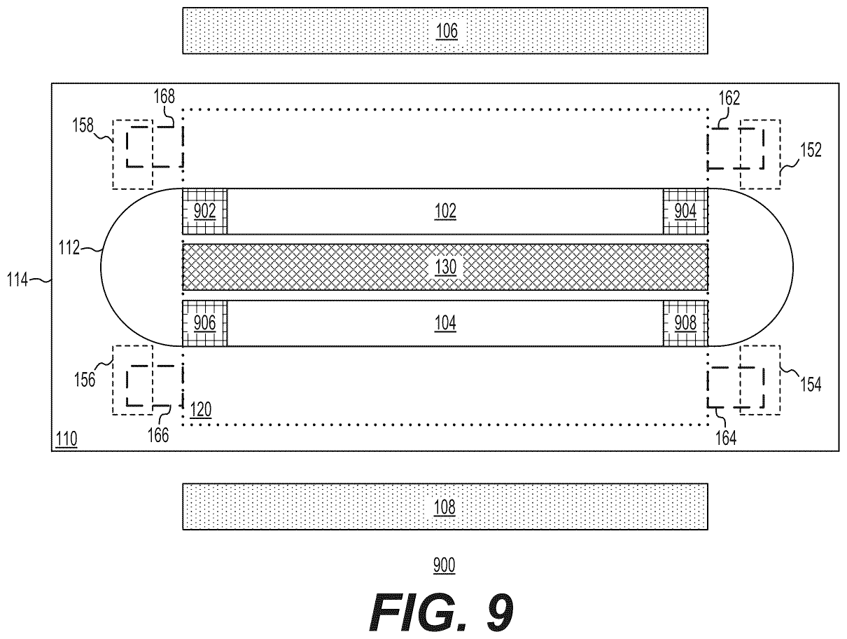

FIG. 9 shows a combination of sidewall leakage improvement regions and opposite doping-type parasitic channel inserts formed in an LDMOS device 900 in accordance with one example. FIG. 9 shows sidewall leakage improvement (SLI) regions that are formed in a similar fashion as described earlier with respect to LDMOS device 100 of FIG. 1 and FIG. 9 further shows opposite doping-type channel regions 902, 904, 906, and 908 formed in a similar fashion as described earlier with respect to LDMOS device 200 of FIG. 2. The same or similar regions or structures that are shown in FIG. 9 are referred to using the same or similar reference numbers as used in FIG. 1 and/or FIG. 2.

As before, example LDMOS device 900 is formed in an N-well associated with a P-type substrate and includes two source regions and two drain regions with associated drain extension regions. LDMOS device 900 includes a source region 102, another source region 104, a drain region 106, and another drain region 108. Each of source regions 102 and 104 and drain regions 106 and 108 are implemented as N+ type regions in this example. LDMOS device 900 further includes a gate electrode 110, whose inner edge is indicated by reference number 112 and whose outer edge is indicated by reference number 114. Within the enclosure formed by the inner edge of the gate electrode, a body contact 130 is formed. In this example, body contact 130 is a P+ type body contact. Similar considerations apply to body contact 130 in FIG. 9 as for the body contact 130 described earlier with respect to FIG. 1. Moreover, similar considerations apply to opposite doping-type parasitic channel regions 902, 904, 906, and 908 in FIG. 9 as for the opposite doping-type channel regions 202, 204, 206, and 208 described earlier with respect to FIG. 2.

With continued reference to FIG. 9, LDMOS device 900 further includes an active region 120, which may correspond to the region between the dielectric isolation regions (e.g., shallow-trench isolation (STI) regions) (not shown). In environments with ionizing radiation, positive charge accumulates in the dielectric isolation regions along the edges of active region 120. This can lead to the formation of a parasitic transistor between the source and the drain of the device. As an example, a parasitic transistor may be formed between source region 102 and drain region 106. Another parasitic transistor may be formed between source region 104 and drain region 108. Because such parasitic transistors are not under the control of the gate associated with the device, they are a source of off-state leakage current.

To eliminate, or delay, the formation of such parasitic transistors, as described before with respect to FIG. 1, during the formation of the LDMOS device, implants 152, 154, 156, and 158 are performed. In addition, sidewall leakage improvement (SLI) regions 162, 164, 166, and 168 are formed in a similar fashion, as described earlier with respect to FIG. 1. Implants 152, 154, 156, and 158 are formed such that they cover as much area of SLI regions 162, 164, 166, and 168 without impinging upon the channel area of LDMOS device 900. As noted earlier, with the SLI regions 162, 164, 166, and 168, the effective channel length of the parasitic transistor is greater than the transistor channel length. Moreover, implants 152, 154, 156, and 158 further improve the total ionizing dose (TID) performance of the transistor by raising the threshold voltage of any parasitic transistors that may form in LDMOS device 900.

Still referring to FIG. 9, as described earlier with respect to FIG. 2, opposite doping-type channel regions 902, 904, 906, and 908 are formed as part of LDMOS device 900. As an example, the opposite doping-type channel regions 902, 904, 906, and 908 are formed using a P-type implant to separate the LDMOS source regions (e.g., source regions 102 and 104) from any parasitic transistors that may form in LDMOS device 900. Each of the opposite doping-type channel regions 902, 904, 906, and 908 creates a junction which isolates the source of the intrinsic transistor, which also acts as the source of the parasitic transistor, from the channel of the parasitic transistor. This makes it significantly more difficult for the parasitic transistor to form. For the same width of the active region, the effective width of the LDMOS transistor is decreased by the opposite doping-type channel regions 902, 904, 906, and 908.

Implants 152, 154, 156, and 158 and SLI regions 162, 164, 166, and 168 and opposite doping-type channel regions 902, 904, 906, and 908 can be formed regardless of whether LDMOS device 900 is fabricated in bulk silicon, silicon films, such as silicon-on-insulator (SOI) substrates, or another semiconductor material. In the case of an SOI substrate, a P-type semiconductor layer may be formed in the SOI substrate. Although FIG. 9 shows a specific configuration of implants 152, 154, 156, and 158 and SLI regions 162, 164, 166, and 168 in terms of their location and shape, the implants and SLI regions may be formed in additional, or alternative, locations and may have different shapes than shown in FIG. 9. Although FIG. 9 shows a specific configuration of opposite doping-type channel regions 902, 904, 906, and 908 in terms of their location and shape, they may be formed in additional, or alternative, locations and may have different shapes than shown in FIG. 9. In addition, although FIG. 9 shows drain regions 106 and 108 formed outside of active region 120 and source regions 102 and 104 formed inside active region 120, the arrangement could be reversed, such that drain regions 106 and 108 are formed inside an altered active region 120 and source regions 102 and 104 are formed in different active regions outside of active region 120. The SLI regions described herein, and the opposite doping-type parasitic channel regions can be used with other high-voltage device designs, including vertical double-diffused metal-oxide semiconductor (VDMOS) devices and TMOS devices.

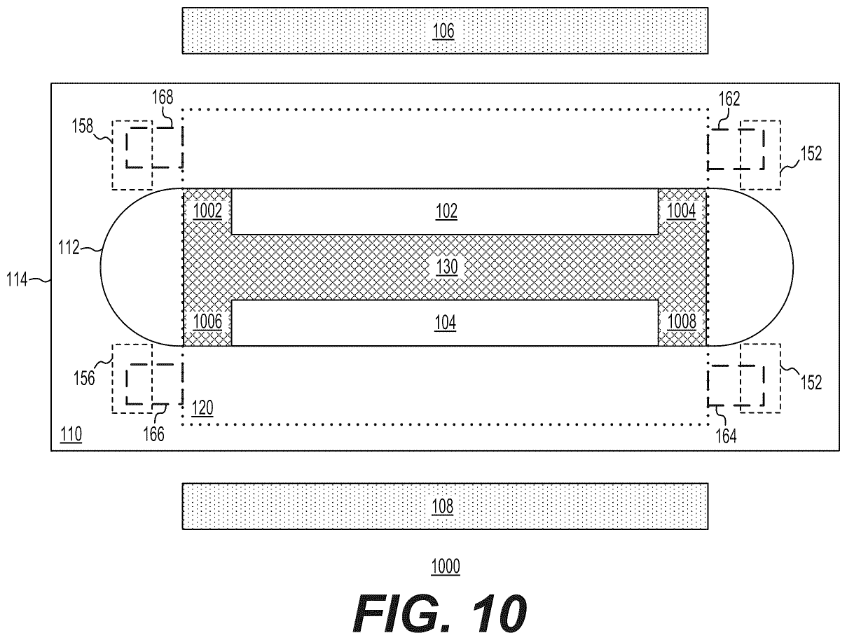

FIG. 10 shows a combination of sidewall leakage improvement regions and opposite doping-type parasitic channel inserts formed in an LDMOS device 1000 in accordance with one example. FIG. 10 shows sidewall leakage improvement (SLI) regions that are formed in a similar fashion as described earlier with respect to LDMOS device 100 of FIG. 1 and FIG. 10 further shows opposite doping-type parasitic channel regions 1002, 1004, 1006, and 1008 formed in a similar fashion as described earlier with respect to LDMOS device 300 of FIG. 3. The same or similar regions or structures that are shown in FIG. 10 are referred to using the same or similar reference numbers as used in FIG. 1 and/or FIG. 3.

As before, example LDMOS device 1000 is formed in a P-type substrate and includes two source regions and two drain regions and associated drain extension regions. LDMOS device 1000 includes a source region 102, another source region 104, a drain region 106, and another drain region 108. Each of source regions 102 and 104 and drain regions 106 and 108 are implemented as N+ type regions in this example. LDMOS device 1000 further includes a gate electrode 110, whose inner edge is indicated by reference number 112 and whose outer edge is indicated by reference number 114. Within the enclosure formed by the inner edge of gate electrode a body contact 130 is formed. In this example, body contact 130 is a P+ type body contact. Similar considerations apply to body contact 130 in FIG. 10 as for the body contact 130 described earlier with respect to FIG. 1. Moreover, similar considerations apply to opposite doping-type parasitic channel regions 1002, 1004, 1006, and 1008 in FIG. 10 as for the opposite doping-type channel regions 302, 304, 306, and 308 described earlier with respect to FIG. 3.

With continued reference to FIG. 10, LDMOS device 1000 further includes an active region 120, which may correspond to the region between the dielectric isolation regions (e.g., shallow-trench isolation (STI) regions) (not shown). In environments with ionizing radiation, positive charge accumulates in the dielectric isolation regions along the edges of active region 120. This can lead to the formation of a parasitic transistor between the source and the drain of the device. As an example, a parasitic transistor may be formed between source region 102 and drain region 106. Another parasitic transistor may be formed between source region 104 and drain region 108. Because such parasitic transistors are not under the control of the gate associated with the device, they are a source of off-state leakage current, as well.

To eliminate, or delay, the formation of such parasitic transistors, as described before with respect to FIG. 1, during the formation of the LDMOS device, implants 152, 154, 156, and 158 are performed. In addition, sidewall leakage improvement (SLI) regions 162, 164, 166, and 168 are formed in a similar fashion, as described earlier with respect to FIG. 1. Implants 152, 154, 156, and 158 are formed such that they cover as much area of SLI regions 162, 164, 166, and 168 without impinging upon the channel area of LDMOS device 900. As noted earlier, with the SLI regions 162, 164, 166, and 168, the effective channel length of the parasitic transistor is greater than the transistor channel length. Moreover, implants 152, 154, 156, and 158 further improve the total ionizing dose (TID) performance of the transistor by raising the threshold voltage of any parasitic transistors that may form in LDMOS device 1000.

Still referring to FIG. 10, as described earlier with respect to FIG. 3, using the same implant for forming body contact 130, opposite doping-type channel regions 1002, 1004, 1006, and 1008 are formed as part of LDMOS device 1000. As an example, the P+ type body contact and the opposite doping-type channel regions 1002, 1004, 1006, and 1008 may have a doping concentration of 1×10²⁰ atoms per cm³ and the P− type substrate may have a doping concentration of 1×10¹⁶ atoms per cm³. The atoms may correspond to boron or another P-type implant material. The opposite doping-type channel regions 1002, 1004, 1006, and 1008 are formed to separate the LDMOS source regions (e.g., source regions 102 and 104) from any parasitic transistors that may form in LDMOS device 1000. Each of the opposite doping-type channel regions 1002, 1004, 1006, and 1008 creates a junction which isolates the source of the intrinsic transistor, which also acts as the source of the parasitic transistor, from the channel of the parasitic transistor. This makes it significantly more difficult for the parasitic transistor to form. For the same width of the active region, the effective width of the LDMOS transistor is decreased by the opposite doping-type channel regions 1002, 1004, 1006, and 1008.

Implants 152, 154, 156, and 158 and SLI regions 162, 164, 166, and 168 and opposite doping-type channel regions 1002, 1004, 1006, and 1008 can be formed regardless of whether LDMOS device 1000 is fabricated in bulk silicon, silicon films, such as silicon-on-insulator (SOI) substrates, or another semiconductor material. In the case of an SOI substrate, a P-type semiconductor layer may be formed in the SOI substrate. Although FIG. 10 shows a specific configuration of implants 152, 154, 156, and 158 and SLI regions 162, 164, 166, and 168 in terms of their location and shape, the implants and SLI regions may be formed in additional, or alternative, locations and may have different shapes than shown in FIG. 10. Although FIG. 10 shows a specific configuration of opposite doping-type channel regions 1002, 1004, 1006, and 1008 in terms of their location and shape, they may be formed in additional, or alternative, locations and may have different shapes than shown in FIG. 10. In addition, although FIG. 10 shows drain regions 106 and 108 formed outside of active region 120 and source regions 102 and 104 formed inside active region 120, the arrangement could be reversed, such that drain regions 106 and 108 are formed inside an altered active region 120 and source regions 102 and 104 are formed in different active regions outside of active region 120. The SLI regions described herein, and the opposite doping-type parasitic channel regions can be used with other high-voltage device designs, including vertical double-diffused metal-oxide semiconductor (VDMOS) devices and TMOS devices.

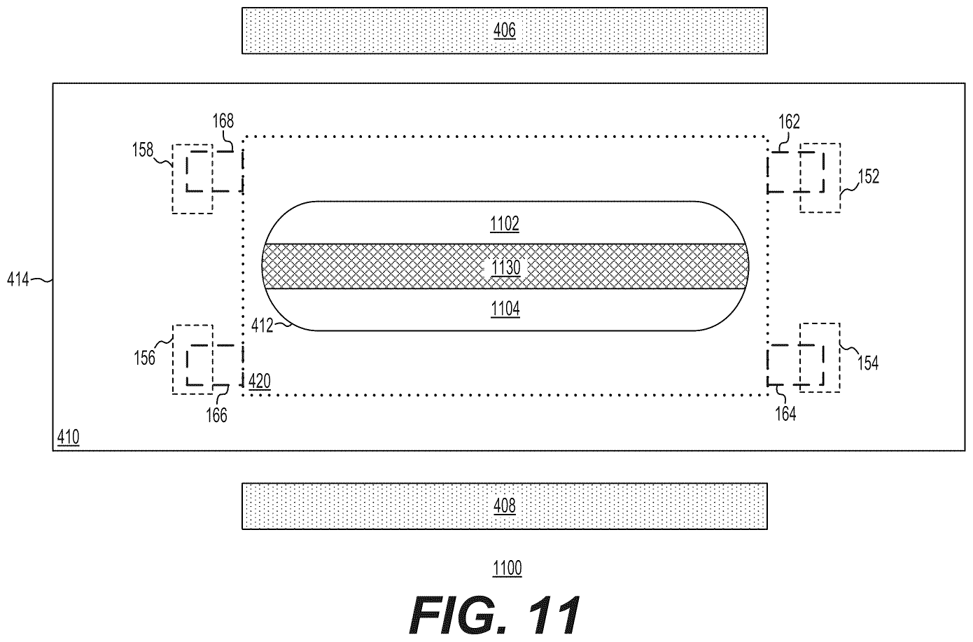

FIG. 11 shows a combination of sidewall leakage improvement regions and a gate-controlled series transistor formed in an LDMOS device in accordance with one example. FIG. 11 shows sidewall leakage improvement (SLI) regions that are formed in a similar fashion as described earlier with respect to LDMOS device 100 of FIG. 1 and FIG. 11 further shows a gate-controlled transistor formed in series with the parasitic channel in a similar fashion as described earlier with respect to LDMOS device 400 of FIG. 4. The same or similar regions or structures that are shown in FIG. 11 are referred to using the same or similar reference numbers as used in FIG. 1 and/or FIG. 4.

As before, example LDMOS device 1100 is formed in a P-type substrate and includes two source regions and two drain regions with associated drain extension regions. LDMOS device 1100 includes a source region 1102, another source region 1104, a drain region 406, and another drain region 408. Each of source regions 1102 and 1104 and drain regions 406 and 408 are implemented as N+ type regions in this example. LDMOS device 1100 further includes a gate electrode 410, whose inner edge is indicated by reference number 412 and whose outer edge is indicated by reference number 414. As described earlier with respect to FIG. 4, unlike source regions 102 and 104 of FIG. 1, source regions 1102 and 1104 are formed such that the gate material between the inner edge (reference number 412) of gate electrode 410 separates the N+ source regions 1102 and 1104 from the parasitic channel (e.g., formed because of the accumulation of the positive charge in the dielectric isolation regions along the edges of active region). As a result, the leakage path between the source (e.g., source region 1102) and the drain (e.g., drain region 406) now consists of two transistors in series—a gate-controlled MOSFET and the parasitic transistor. Since one of these transistors is under the control of the gate electrode, as long as its channel length is greater than the intrinsic transistor channel length, it will be switched off when the intrinsic transistor is switched off, and, therefore, limit the total leakage current through the parasitic transistor. Within the enclosure formed by the inner edge of gate electrode a body contact 1130 is formed. In this example, body contact 1130 is a P+ type body contact. Similar considerations apply to body contact 1130 as to body contact 130 described earlier with respect to FIG. 1.

With continued reference to FIG. 11, LDMOS device 1100 further includes an active region 420, which may correspond to the region between the dielectric isolation regions (e.g., shallow-trench isolation (STI) regions) (not shown). In environments with ionizing radiation, positive charge accumulates in the dielectric isolation regions along the edges of active region 420. This can lead to the formation of a parasitic transistor between the source and the drain of the device. As an example, a parasitic transistor may be formed between source region 1102 and drain region 406. Another parasitic transistor may be formed between source region 1104 and drain region 408. Because such parasitic transistors are not under the control of the gate associated with the device, they are a source of off-state leakage current, as well.

To eliminate, or delay, the formation of such parasitic transistors, as described before with respect to FIG. 1, during the formation of the LDMOS device, implants 152, 154, 156, and 158 are performed. In addition, sidewall leakage improvement (SLI) regions 162, 164, 166, and 168 are formed in a similar fashion, as described earlier with respect to FIG. 1. Implants 152, 154, 156, and 158 are formed such that they cover as much area of SLI regions 162, 164, 166, and 168 without impinging upon the channel area of LDMOS device 1100. As noted earlier, with the SLI regions 162, 164, 166, and 168, the effective channel length of the parasitic transistor is greater than the transistor channel length. Moreover, implants 152, 154, 156, and 158 further improve the total ionizing dose (TID) performance of the transistor by raising the threshold voltage of any parasitic transistors that may form in LDMOS device 1100.

Implants 152, 154, 156, and 158 and SLI regions 162, 164, 166, and 168 and the gate-controlled transistor, in series with the parasitic channel, can be formed regardless of whether LDMOS device 1100 is fabricated in bulk silicon, silicon films, such as silicon-on-insulator (SOI) substrates, or another semiconductor material. In the case of an SOI substrate, a P-type semiconductor layer may be formed in the SOI substrate. Although FIG. 11 shows a specific configuration of implants 152, 154, 156, and 158 and SLI regions 162, 164, 166, and 168 in terms of their location and shape, the implants and SLI regions may be formed in additional, or alternative, locations and may have different shapes than shown in FIG. 11. In addition, although FIG. 11 shows drain regions 406 and 408 formed outside of active region 420 and source regions 1102 and 1104 formed inside active region 420, the arrangement could be reversed, such that drain regions 406 and 408 are formed inside an altered active region 420 and source regions 1102 and 1104 are formed in different active regions outside of active region 420. The SLI regions described herein and the gate-controlled transistor, in series with the parasitic channel, can be used with other high-voltage device designs, including vertical double-diffused metal-oxide semiconductor (VDMOS) devices and TMOS devices.

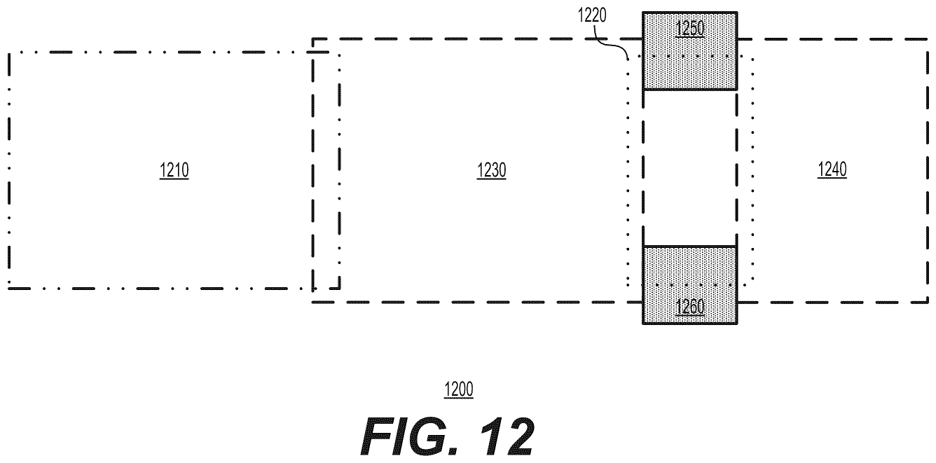

FIG. 12 shows a top view 1200 of the non-isolated LDMOS device 600 shown in FIG. 6 in accordance with one example. Region 1210 corresponds to the channel and the source active regions of the non-isolated LDMOS device 600 of FIG. 6. In the top view 1200 shown in FIG. 12, in this example, region 1230 shows a view of an aggregation of regions 632, 634, and 636 shown in FIG. 6. In addition, region 1240 shows a view of an aggregation of regions 642 and 644 shown in FIG. 6. Both FIG. 6 and FIG. 12 show these regions are below and on the sidewalls of the shallow trench isolation (STI) regions 624 and 626 of FIG. 6. The top view 1200 shows these regions along the “West” and the “East” STI sidewalls of the drain active region 1220. Moreover, in this example, region 1250 corresponds to regions 636 and 644 of FIG. 6 along the “North” STI sidewall corresponding to drain active region 1220 and regions 632 and 642 of FIG. 6 under the “North” STI region. The extension distance under the STI region in the “North” direction can be varied from very small to very large depending on the STI quality and the size of the TID improvement regions and other regions in the device. In addition, in this example, region 1260 corresponds to regions 636 and 644 of FIG. 6 along the “South” STI sidewall corresponding to drain active region 1220 and regions 632 and 642 of FIG. 6 under the “South” STI region. The extension distance under the STI region in the “South” direction can be varied from very small to very large depending on the STI quality and the size of the TID improvement regions and other regions in the device.

Collectively, this means that, in this example, all of the STI sidewalls surrounding the drain active region 1220 have adjacent doped regions like regions 636 and 644 of FIG. 6 and all of the STI regions below drain active region 1220 have adjacent doped regions like regions 632 and 642 of FIG. 6. In one example implementation, the same implant would form all of the TID improvement regions described with respect to the top view 1200 in FIG. 12.

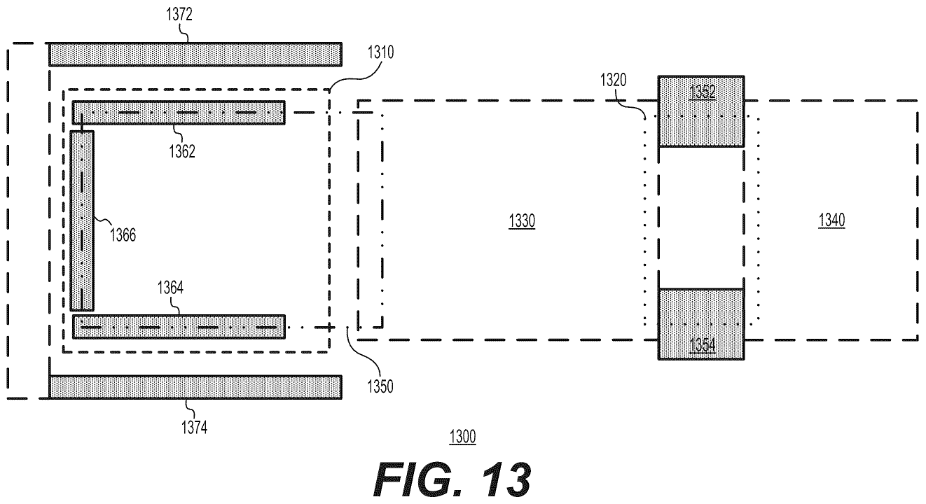

FIG. 13 shows a top view 1300 of the isolated LDMOS device 700 shown in FIG. 7 in accordance with one example. In the top view 1300 shown in FIG. 13, in this example, region 1330 shows a view of an aggregation of regions 734, 732 and 736 shown in FIG. 7. In addition, region 1340 shows a view of an aggregation of regions 742 and 744 shown in FIG. 7. Both FIG. 7 and FIG. 13 show these regions as below and on the sidewalls of the shallow trench isolation (STI) regions 724 and 726 of FIG. 7. The top view 1300 shows these regions along the “West” and the “East” STI sidewalls of the drain active region 1320. Moreover, in this example, region 1352 corresponds to regions 736 and 744 of FIG. 7 along the “North” STI sidewall corresponding to drain active region 1320 and regions 732 and 742 of FIG. 7 under the “North” STI region. The extension distance under the STI region in the “North” direction can be varied from very small to very large depending on the STI quality and the size of the TID improvement regions and other regions in the device. In addition, in this example, region 1354 corresponds to regions 736 and 744 of FIG. 7 along the “South” STI sidewall corresponding to drain active region 1320 and regions 732 and 742 of FIG. 7 under the “South” STI region. As noted earlier, the extension distance under the STI region in the “South” direction can be varied from very small to very large depending on the STI quality and the size of the TID improvement regions and other regions in the device.

Collectively, this means that, in this example, all of the STI sidewalls surrounding the drain active region 1320 have adjacent doped regions like regions 736 and 744 of FIG. 7 and all of the STI regions below drain active region 1320 have adjacent doped regions like regions 732 and 742 of FIG. 7. In one example implementation, the same implant would form all of the TID improvement regions described with respect to the top view 1300 in FIG. 13.

With continued reference to FIG. 13, region 1366 shows an aggregation of region 752 (adjacent to the STI sidewall) and region 748 (adjacent to the STI bottom) on the “West” side of the channel and source active region 1350 shown in top view 1300. In order to maximize device performance, region 1366 should be enclosed within region 1310. In addition, region 1362 shows an aggregation of region 752 (adjacent to the STI sidewall) and region 748 (adjacent to the STI bottom) on the “North” side of the channel and source active region 1350 shown in top view 1300. In this example, region 1362 needs to stay completely within the P-body region 1310 to maximize device performance. In other words, region 1362 cannot cross the P-body region boundary. The exact distance by which the P-Body region 1310 must enclose region 1362 depends on the STI quality, the TID regions, the desired device voltage rating and the details of the P-body and the isolating N-Well doping profiles. Region 1364 shows an aggregation of region 752 (adjacent to the STI sidewall) and region 748 (adjacent to the STI bottom) on the “South” side of the channel and source active region 1350 shown in top view 1300. In this example, like region 1362, region 1364 also needs to stay completely within the P-body region 1310. In other words, region 1362 cannot cross the P-body region boundary. Once again, the exact distance by which the P-Body region 1310 must enclose region 1364 depends on the STI quality, the TID regions, the desired device voltage rating and the details of the P-body and the isolating N-Well doping profiles. Although shown as three separate regions in FIG. 13, regions 1362, 1364 and 1366 can be merged in any combination.

Still referring to FIG. 13, regions 1372 and 1374 correspond to regions of the isolated LDMOS device 700 of FIG. 7 that are under the STI region, outside of the P-body region 1310, and that are within the isolating N-Well along the “North” and the “South” boundaries, respectively. The exact placement between the boundaries of the P-body region 1310 and the isolating N-Well depends on the STI quality, the TID regions, the desired device voltage rating and the details of the P-body and the isolating N-Well doping profiles. As noted earlier, in one example implementation, the same implant would form all of the TID improvement regions described with respect to the top view 1300 in FIG. 13.

In conclusion, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a first opposite doping-type region formed within the active region towards a first distal end of the active region to separate the source region from a parasitic transistor. The high-breakdown voltage semiconductor device may further comprise a second opposite doping-type region formed within the active region towards a second distal end, opposite from the first distal end, of the active region to separate the source region from a second parasitic transistor, where the source region has a first conductivity type, and where each of the first opposite doping-type region and the second opposite doping-type region has a second conductivity type, opposite of the first conductivity type.

The high-breakdown voltage semiconductor device may further comprise a second source region and a second drain region. The high-breakdown voltage semiconductor device may further comprise a third opposite doping-type region formed within the active region towards the first distal end of the active region to separate the second source region from a third parasitic transistor.

The high-breakdown voltage semiconductor device may further comprise a fourth opposite doping-type region formed within the active region towards the second distal end of the active region to separate the second source region from a fourth parasitic transistor formed between the second source region and the second drain region. The second source region may have the first conductivity type, and each of the third opposite doping-type region and the fourth opposite doping-type region may have the second conductivity type.

The high-breakdown voltage semiconductor device may further comprise a drain extension region, a first total ionizing dosage (TID) improvement region, and a second TID improvement region, where the first TID improvement region extends parallel to the drain extension region towards a first distal end of the drain extension region, and the second TID improvement region extends parallel to the drain extension region towards a second distal end, opposite to the first distal end, of the drain extension region. The high-breakdown voltage semiconductor device may further comprise a second drain extension region, a third total ionizing dosage (TID) improvement region, and a fourth TID improvement region, where the third TID improvement region extends parallel to the second drain extension region towards a first distal end of the second drain extension region, and the fourth TID improvement region extends parallel to the second drain extension region towards a second distal end, opposite to the first distal end, of the second drain extension region.

The high-breakdown voltage semiconductor device may further comprise one of a laterally-diffused metal oxide semiconductor (LDMOS) device, a vertical double-diffused metal-oxide semiconductor (VDMOS) device, a trench metal-oxide semiconductor (TMOS) device, or an insulated-gate bipolar transistor (IGBT). The high-breakdown voltage semiconductor device may further comprise an LDMOS, VDMOS, TMOS, or IGBT transistor coupled in series with a low-voltage metal-oxide semiconductor (MOS) transistor, where the low-voltage MOS transistor has a lower breakdown voltage than the high-breakdown voltage.

In another aspect, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a gate electrode formed within the active region, where the gate electrode region is shaped such that: (1) a first gate-controlled series transistor is formed in series with a first parasitic transistor, resulting in a first pair of series transistors formed in parallel with a first intrinsic transistor formed between the source region and the drain region, and (2) a second gate-controlled series transistor is formed in series with a second parasitic transistor, resulting in a second pair of series transistors formed in parallel with the first intrinsic transistor formed between the source region and the drain region.

The high-breakdown voltage semiconductor device may further comprise a second source region and a second drain region. The gate electrode region may further be shaped such that: (1) a third gate-controlled series transistor is formed in series with a third parasitic transistor, resulting in a third pair of series transistors formed in parallel with a second intrinsic transistor formed between the second source region and the second drain region, and (2) a fourth gate-controlled series transistor is formed in series with a fourth parasitic transistor, resulting in a fourth pair of series transistors formed in parallel with the second intrinsic transistor formed between the second source region and the second drain region.

The high-breakdown voltage semiconductor device may further comprise a drain extension region, a first total ionizing dosage (TID) improvement region, and a second TID improvement region, where the first TID improvement region extends parallel to the drain extension region towards a first distal end of the drain extension region, and the second TID improvement region extends parallel to the drain extension region towards a second distal end, opposite to the first distal end, of the drain extension region. The high-breakdown voltage semiconductor device may further comprise a second drain extension region, a third total ionizing dosage (TID) improvement region, and a fourth TID improvement region, where the third TID improvement region extends parallel to the second drain extension region towards a first distal end of the second drain extension region, and the fourth TID improvement region extends parallel to the second drain extension region towards a second distal end, opposite to the first distal end, of the second drain extension region.

The high-breakdown voltage semiconductor device may further comprise one of a laterally-diffused metal oxide semiconductor (LDMOS) device, a vertical double-diffused metal-oxide semiconductor (VDMOS) device, a trench metal-oxide semiconductor (TMOS) device or an insulated-gate bipolar transistor (IGBT). The high-breakdown voltage semiconductor device may further comprise an LDMOS, VDMOS, TMOS, or IGBT transistor coupled in series with a low-voltage metal-oxide semiconductor (MOS) transistor, where the low-voltage MOS transistor has a lower breakdown voltage than the high-breakdown voltage.

In yet another aspect, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a first opposite doping-type region formed within the active region towards a first distal end of the active region to separate the source region from a first parasitic transistor. The high-breakdown voltage semiconductor device may further comprise a second opposite doping-type region formed within the active region towards a second distal end, opposite from the first distal end, of the active region to separate the source region from a second parasitic transistor, where the source region has a first conductivity type, and where each of the first opposite doping-type region and the second opposite doping-type region has a second conductivity type, opposite of the first conductivity type.

The high-breakdown voltage semiconductor device may further comprise a channel region associated with the source region and the drain region. The high-breakdown voltage semiconductor device may further comprise a first sidewall leakage improvement (SLI) region formed towards a first distal end of the channel region to increase an effective channel length of the first parasitic transistor formed in the high-breakdown voltage device relative to a channel length of a first intrinsic transistor formed in the high-breakdown voltage device. The high-breakdown voltage semiconductor device may further comprise a second sidewall leakage improvement (SLI) region formed towards a second distal end, opposite from the first distal end, of the channel region to increase an effective channel length of the second parasitic transistor formed in the high-breakdown voltage device relative to a channel length of the first intrinsic transistor formed in the high-breakdown voltage device.

The high-breakdown voltage semiconductor device may further comprise a second source region and a second drain region. The high-breakdown voltage semiconductor device may further comprise a third opposite doping-type region formed within the active region towards the first distal end of the active region to separate the second source region from a third parasitic transistor. The high-breakdown voltage semiconductor device may further comprise a fourth opposite doping-type region formed within the active region towards the second distal end of the active region to separate the second source region from a fourth parasitic transistor formed between the second source region and the second drain region, where the second source region has the first conductivity type, and where each of the third opposite doping-type region and the fourth opposite doping-type region has the second conductivity type.

The high-breakdown voltage semiconductor device may further comprise a second channel region associated with the second source region and the second drain region. The high-breakdown voltage semiconductor device may further comprise a third sidewall leakage improvement (SLI) region formed towards a first distal end of the second channel region to increase an effective channel length of the third parasitic transistor formed in the high-breakdown voltage device relative to a channel length of a third intrinsic transistor formed in the high-breakdown voltage device. The high-breakdown voltage semiconductor device may further comprise a fourth sidewall leakage improvement (SLI) region formed towards a second distal end, opposite from the first distal end, of the second channel region to increase an effective channel length of the fourth parasitic transistor formed in the high-breakdown voltage device relative to a channel length of a fourth intrinsic transistor formed in the high-breakdown voltage device.

The high-breakdown voltage semiconductor device may further comprise an implant resulting in an increase of a respective threshold voltage associated with the parasitic transistor, the second parasitic transistor, the third parasitic transistor, and the fourth parasitic transistor. The high-breakdown voltage semiconductor device may further comprise a drain extension region, a first isolation region formed within the drain extension region, and a second isolation region formed within the drain extension region, where: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

The high-breakdown voltage semiconductor device may further comprise an isolating well. The high-breakdown voltage semiconductor device may further comprise a first isolation region formed within the isolating well, and a second isolation region formed within the isolating well, where: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

The high-breakdown voltage semiconductor device may further comprise one of a laterally-diffused metal oxide semiconductor (LDMOS) device, a vertical double-diffused metal-oxide semiconductor (VDMOS) device, a trench metal-oxide semiconductor (TMOS) device, or an insulated-gate bipolar transistor (IGBT). The high-breakdown voltage semiconductor device may further comprise an LDMOS, VDMOS, TMOS, or IGBT transistor coupled in series with a low-voltage metal-oxide semiconductor (MOS) transistor, where the low-voltage MOS transistor has a lower breakdown voltage than the high-breakdown voltage. The high-breakdown voltage semiconductor device may further comprise a body region formed within an isolation well, where the high-breakdown voltage semiconductor device further comprises an isolation region formed partially within the isolation well and the body region, and where the high-breakdown voltage semiconductor device further comprises a first TID improvement region formed below the isolation region, a second TID improvement region formed, within the body region, adjacent to a side wall of the isolation region, and a third TID improvement region formed, within the body region, below the isolation region.

In another aspect, the present disclosure relates to a high-breakdown voltage semiconductor device. The high-breakdown voltage semiconductor device may comprise a source region and a drain region, where the high-breakdown voltage semiconductor device is configured to withstand a high-breakdown voltage between the drain region and the source region. The high-breakdown voltage semiconductor device may further comprise an active region associated with the high-breakdown voltage semiconductor device.

The high-breakdown voltage semiconductor device may further comprise a gate electrode formed within the active region, where the gate electrode region is shaped such that: (1) a first gate-controlled series transistor is formed in series with a first parasitic transistor, resulting in a first pair of series transistors formed in parallel with a first intrinsic transistor formed between the source region and the drain region, and (2) a second gate-controlled series transistor formed in series with a second parasitic transistor, resulting in a second pair of series transistors formed in parallel with the first intrinsic transistor formed between the source region and the drain region. The high-breakdown voltage semiconductor device may further comprise a channel region associated with the source region and the drain region.

The high-breakdown voltage semiconductor device may further comprise a first sidewall leakage improvement (SLI) region formed towards a first distal end of the channel region to increase an effective channel length of the first parasitic transistor formed in the high-breakdown voltage device relative to a channel length of the first intrinsic transistor formed in the high-breakdown voltage device. The high-breakdown voltage semiconductor device may further comprise a second sidewall leakage improvement (SLI) region formed towards a second distal end, opposite from the first distal end, of the channel region to increase an effective channel length of the second parasitic transistor formed in the high-breakdown voltage device relative to a channel length of the first intrinsic transistor formed in the high-breakdown voltage device.

The high-breakdown voltage semiconductor device may further comprise a second source region and a second drain region. The gate electrode region may further be shaped such that: (1) a third gate-controlled series transistor is formed in series with a third parasitic transistor, resulting in a third pair of series transistors formed in parallel with a second intrinsic transistor formed between the second source region and the second drain region, and (2) a fourth gate-controlled series transistor is formed in series with a fourth parasitic transistor, resulting in a fourth pair of series transistors formed in parallel with the second intrinsic transistor formed between the second source region and the second drain region.

The high-breakdown voltage semiconductor device may further comprise a second channel region associated with the second source region and the second drain region. The high-breakdown voltage semiconductor device may further comprise a third sidewall leakage improvement (SLI) region formed towards a first distal end of the second channel region to increase an effective channel length of the third parasitic transistor formed in the high-breakdown voltage device relative to a channel length of a third intrinsic transistor formed in the high-breakdown voltage device. The high-breakdown voltage semiconductor device may further comprise a fourth sidewall leakage improvement (SLI) region formed towards a second distal end, opposite from the first distal end, of the second channel region to increase an effective channel length of the fourth parasitic transistor formed in the high-breakdown voltage device relative to a channel length of a fourth intrinsic transistor formed in the high-breakdown voltage device.

The first SLI region may be formed by performing an implant resulting in an increase of a threshold voltage associated with the parasitic transistor. The second SLI region may be formed by performing an implant resulting in an increase of a threshold voltage associated with the second parasitic transistor, The third SLI region may be formed by performing an implant resulting in an increase of a threshold voltage associated with the third parasitic transistor. The fourth SLI region may be formed by performing an implant resulting in an increase of a threshold voltage associated with the fourth parasitic transistor.

The high-breakdown voltage semiconductor device may further comprise one of a laterally-diffused metal oxide semiconductor (LDMOS) device, a vertical double-diffused metal-oxide semiconductor (VDMOS) device, a trench metal-oxide semiconductor (TMOS) device, or an insulated-gate bipolar transistor (IGBT). The high-breakdown voltage semiconductor device may further comprise a drain extension region, a first isolation region formed within the drain extension region, and a second isolation region formed within the drain extension region, where: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

The high-breakdown voltage semiconductor device may further comprise an isolating well. The high-breakdown voltage semiconductor device may further comprise a first isolation region formed within the isolating well, and a second isolation region formed within the isolating well, where: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

The high-breakdown voltage semiconductor device may further comprise a body region formed within an isolation well. The high-breakdown voltage semiconductor device may further comprise an isolation region formed partially within the isolation well and the body region. The high-breakdown voltage semiconductor device may further comprise a first TID improvement region formed below the isolation region, a second TID improvement region formed, within the body region, adjacent to a side wall of the isolation region, and a third TID improvement region formed, within the body region, below the isolation region.

It is to be understood that the processes and components depicted herein are merely exemplary. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A high-breakdown voltage semiconductor device comprising:
a source region;
a drain region, wherein the high-breakdown voltage semiconductor device is configured to withstand a high-breakdown voltage between the drain region and the source region;
an active region associated with the high-breakdown voltage semiconductor device;
a first opposite doping-type region formed within the active region towards a first distal end of the active region to separate the source region from a parasitic transistor; and
a second opposite doping-type region formed within the active region towards a second distal end, opposite from the first distal end, of the active region to separate the source region from a second parasitic transistor, wherein the source region has a first conductivity type, and wherein each of the first opposite doping-type region and the second opposite doping-type region has a second conductivity type, opposite of the first conductivity type.

2. The high-breakdown voltage semiconductor device of claim 1, further comprising:
a second source region and a second drain region;
a third opposite doping-type region formed within the active region towards the first distal end of the active region to separate the second source region from a third parasitic transistor; and
a fourth opposite doping-type region formed within the active region towards the second distal end of the active region to separate the second source region from a fourth parasitic transistor formed between the second source region and the second drain region, wherein the second source region has the first conductivity type, and wherein each of the third opposite doping-type region and the fourth opposite doping-type region has the second conductivity type.

3. The high-breakdown voltage semiconductor device of claim 1, further comprising a drain extension region, a first total ionizing dosage (TID) improvement region, and a second TID improvement region, wherein the first TID improvement region extends parallel to the drain extension region towards a first distal end of the drain extension region, and the second TID improvement region extends parallel to the drain extension region towards a second distal end, opposite to the first distal end, of the drain extension region.

4. The high-breakdown voltage semiconductor device of claim 3, further comprising a second drain extension region, a third total ionizing dosage (TID) improvement region, and a fourth TID improvement region, wherein the third TID improvement region extends parallel to the second drain extension region towards a first distal end of the second drain extension region, and the fourth TID improvement region extends parallel to the second drain extension region towards a second distal end, opposite to the first distal end, of the second drain extension region.

5. The high-breakdown voltage semiconductor device of claim 1, wherein the high-breakdown voltage semiconductor device comprises one of a laterally-diffused metal oxide semiconductor (LDMOS) device, a vertical double-diffused metal-oxide semiconductor (VDMOS) device, or a trench metal-oxide semiconductor (TMOS) device.

6. The high-breakdown voltage semiconductor device of claim 1, further comprising an LDMOS transistor coupled in series with a low-voltage metal-oxide semiconductor (MOS) transistor, wherein the low-voltage MOS transistor has a lower breakdown voltage than the high-breakdown voltage.

7. A high-breakdown voltage semiconductor device comprising:
a source region;
a drain region, wherein the high-breakdown voltage semiconductor device is configured to withstand a high-breakdown voltage between the drain region and the source region;
an active region associated with the high-breakdown voltage semiconductor device; and
a gate electrode formed within the active region, wherein the gate electrode region is shaped such that: (1) a first gate-controlled series transistor is formed in series with a first parasitic transistor, resulting in a first pair of series transistors formed in parallel with a first intrinsic transistor formed between the source region and the drain region, and (2) a second gate-controlled series transistor is formed in series with a second parasitic transistor, resulting in a second pair of series transistors formed in parallel with the first intrinsic transistor formed between the source region and the drain region.

8. The high-breakdown voltage semiconductor device of claim 7, further comprising:
a second source region and a second drain region; and
wherein the gate electrode region is further shaped such that: (1) a third gate-controlled series transistor is formed in series with a third parasitic transistor, resulting in a third pair of series transistors formed in parallel with a second intrinsic transistor formed between the second source region and the second drain region, and (2) a fourth gate-controlled series transistor is formed in series with a fourth parasitic transistor, resulting in a fourth pair of series transistors formed in parallel with the second intrinsic transistor formed between the second source region and the second drain region.

9. The high-breakdown voltage semiconductor device of claim 7, further comprising a drain extension region, a first total ionizing dosage (TID) improvement region, and a second TID improvement region, wherein the first TID improvement region extends parallel to the drain extension region towards a first distal end of the drain extension region, and the second TID improvement region extends parallel to the drain extension region towards a second distal end, opposite to the first distal end, of the drain extension region.

10. The high-breakdown voltage semiconductor device of claim 9, further comprising a second drain extension region, a third total ionizing dosage (TID) improvement region, and a fourth TID improvement region, wherein the third TID improvement region extends parallel to the second drain extension region towards a first distal end of the second drain extension region, and the fourth TID improvement region extends parallel to the second drain extension region towards a second distal end, opposite to the first distal end, of the second drain extension region.

11. The high-breakdown voltage semiconductor device of claim 7, wherein the high-breakdown voltage semiconductor device comprises one of a laterally-diffused metal oxide semiconductor (LDMOS) device, a vertical double-diffused metal-oxide semiconductor (VDMOS) device, or a trench metal-oxide semiconductor (TMOS) device.

12. The high-breakdown voltage semiconductor device of claim 7, further comprising an LDMOS transistor coupled in series with a low-voltage metal-oxide semiconductor (MOS) transistor, wherein the low-voltage MOS transistor has a lower breakdown voltage than the high-breakdown voltage.

13. A high-breakdown voltage semiconductor device comprising:
a source region;
a drain region, wherein the high-breakdown voltage semiconductor device is configured to withstand a high-breakdown voltage between the drain region and the source region;
an active region associated with the high-breakdown voltage semiconductor device;
a first opposite doping-type region formed within the active region towards a first distal end of the active region to separate the source region from a first parasitic transistor;
a second opposite doping-type region formed within the active region towards a second distal end, opposite from the first distal end, of the active region to separate the source region from a second parasitic transistor, wherein the source region has a first conductivity type, and wherein each of the first opposite doping-type region and the second opposite doping-type region has a second conductivity type, opposite of the first conductivity type;
a channel region associated with the source region and the drain region;
a first sidewall leakage improvement (SLI) region formed towards a first distal end of the channel region to increase an effective channel length of the first parasitic transistor formed in the high-breakdown voltage device relative to a channel length of a first intrinsic transistor formed in the high-breakdown voltage device; and
a second sidewall leakage improvement (SLI) region formed towards a second distal end, opposite from the first distal end, of the channel region to increase an effective channel length of the second parasitic transistor formed in the high-breakdown voltage device relative to a channel length of the first intrinsic transistor formed in the high-breakdown voltage device.

14. The high-breakdown voltage semiconductor device of claim 13, further comprising:
a second source region and a second drain region;
a third opposite doping-type region formed within the active region towards the first distal end of the active region to separate the second source region from a third parasitic transistor; and
a fourth opposite doping-type region formed within the active region towards the second distal end of the active region to separate the second source region from a fourth parasitic transistor formed between the second source region and the second drain region, wherein the second source region has the first conductivity type, and wherein each of the third opposite doping-type region and the fourth opposite doping-type region has the second conductivity type.

15. The high-breakdown voltage semiconductor device of claim 14, further comprising:
a second channel region associated with the second source region and the second drain region; and
a third sidewall leakage improvement (SLI) region formed towards a first distal end of the second channel region to increase an effective channel length of the third parasitic transistor formed in the high-breakdown voltage device relative to a channel length of a third intrinsic transistor formed in the high-breakdown voltage device; and
a fourth sidewall leakage improvement (SLI) region formed towards a second distal end, opposite from the first distal end, of the second channel region to increase an effective channel length of the fourth parasitic transistor formed in the high-breakdown voltage device relative to a channel length of a fourth intrinsic transistor formed in the high-breakdown voltage device.

16. The high-breakdown voltage semiconductor device of claim 15, further comprising an implant resulting in an increase of a respective threshold voltage associated with the first parasitic transistor, the second parasitic transistor, the third parasitic transistor, and the fourth parasitic transistor.

17. The high-breakdown voltage semiconductor device of claim 13, further comprising a drain extension region, a first isolation region formed within the drain extension region, and a second isolation region formed within the drain extension region, wherein: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

18. The high-breakdown voltage semiconductor device of claim 13, further comprising an isolating well, wherein the high-breakdown voltage semiconductor device further comprises a first isolation region formed within the isolating well, and a second isolation region formed within the isolating well, wherein: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

19. The high-breakdown voltage semiconductor device of claim 13, wherein the high-breakdown voltage semiconductor device comprises one of a laterally-diffused metal oxide semiconductor (LDMOS) device, a vertical double-diffused metal-oxide semiconductor (VDMOS) device, or a trench metal-oxide semiconductor (TMOS) device.

20. The high-breakdown voltage semiconductor device of claim 13, further comprising an LDMOS transistor coupled in series with a low-voltage metal-oxide semiconductor (MOS) transistor, wherein the low-voltage MOS transistor has a lower breakdown voltage than the high-breakdown voltage.

21. The high-breakdown voltage semiconductor device of claim 13, further comprising a body region formed within an isolation well, wherein the high-breakdown voltage semiconductor device further comprises an isolation region formed partially within the isolation well and the body region, and wherein the high-breakdown voltage semiconductor device further comprises a first TID improvement region formed below the isolation region, a second TID improvement region formed, within the body region, adjacent to a side wall of the isolation region, and a third TID improvement region formed, within the body region, below the isolation region.

22. A high-breakdown voltage semiconductor device comprising:
a source region;
a drain region, wherein the high-breakdown voltage semiconductor device is configured to withstand a high-breakdown voltage between the drain region and the source region;
an active region associated with the high-breakdown voltage semiconductor device;
a gate electrode formed within the active region, wherein the gate electrode region is shaped such that: (1) a first gate-controlled series transistor is formed in series with a first parasitic transistor, resulting in a first pair of series transistors formed in parallel with a first intrinsic transistor formed between the source region and the drain region, and (2) a second gate-controlled series transistor formed in series with a second parasitic transistor, resulting in a second pair of series transistors formed in parallel with the first intrinsic transistor formed between the source region and the drain region;
a channel region associated with the source region and the drain region;
a first sidewall leakage improvement (SLI) region formed towards a first distal end of the channel region to increase an effective channel length of the first parasitic transistor formed in the high-breakdown voltage device relative to a channel length of the first intrinsic transistor formed in the high-breakdown voltage device; and
a second sidewall leakage improvement (SLI) region formed towards a second distal end, opposite from the first distal end, of the channel region to increase an effective channel length of the second parasitic transistor formed in the high-breakdown voltage device relative to a channel length of the first intrinsic transistor formed in the high-breakdown voltage device.

23. The high-breakdown voltage semiconductor device of claim 22, further comprising:
a second source region and a second drain region; and
wherein the gate electrode region is further shaped such that: (1) a third gate-controlled series transistor is formed in series with a third parasitic transistor, resulting in a third pair of series transistors formed in parallel with a second intrinsic transistor formed between the second source region and the second drain region, and (2) a fourth gate-controlled series transistor is formed in series with a fourth parasitic transistor, resulting in a fourth pair of series transistors formed in parallel with the second intrinsic transistor formed between the second source region and the second drain region.

24. The high-breakdown voltage semiconductor device of claim 23, further comprising:
a second channel region associated with the second source region and the second drain region; and
a third sidewall leakage improvement (SLI) region formed towards a first distal end of the second channel region to increase an effective channel length of the third parasitic transistor formed in the high-breakdown voltage device relative to a channel length of a third intrinsic transistor formed in the high-breakdown voltage device; and
a fourth sidewall leakage improvement (SLI) region formed towards a second distal end, opposite from the first distal end, of the second channel region to increase an effective channel length of the fourth parasitic transistor formed in the high-breakdown voltage device relative to a channel length of a fourth intrinsic transistor formed in the high-breakdown voltage device.

25. The high-breakdown voltage semiconductor device of claim 24, wherein the first SLI region is formed by performing an implant resulting in an increase of a threshold voltage associated with the first parasitic transistor, wherein the second SLI region is formed by performing an implant resulting in an increase of a threshold voltage associated with the second parasitic transistor, wherein the third SLI region is formed by performing an implant resulting in an increase of a threshold voltage associated with the third parasitic transistor, and wherein the fourth SLI region is formed by performing an implant resulting in an increase of a threshold voltage associated with the fourth parasitic transistor.

26. The high-breakdown voltage semiconductor device of claim 22, wherein the high-breakdown voltage semiconductor device comprises one of a laterally-diffused metal oxide semiconductor (LDMOS) device, a vertical double-diffused metal-oxide semiconductor (VDMOS) device, or a trench metal-oxide semiconductor (TMOS) device.

27. The high-breakdown voltage semiconductor device of claim 22, further comprising a drain extension region, a first isolation region formed within the drain extension region, and a second isolation region formed within the drain extension region, wherein: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

28. The high-breakdown voltage semiconductor device of claim 22, further comprising an isolating well, wherein the high-breakdown voltage semiconductor device further comprises a first isolation region formed within the isolating well, and a second isolation region formed within the isolating well, wherein: (1) a first total ionizing dosage (TID) improvement region is formed adjacent to a first sidewall of the first isolation region, (2) a second TID improvement region is formed adjacent to a second sidewall of the first isolation region, (3) a third TID improvement region is formed below the first isolation region, (4) a fourth TID improvement region is formed adjacent to a sidewall of the second isolation region, and (5) a fifth TID improvement region is formed below the first isolation region.

29. The high-breakdown voltage semiconductor device of claim 22, further comprising a body region formed within an isolation well wherein the high-breakdown voltage semiconductor device further comprises an isolation region formed partially within the isolation well and the body region, and wherein the high-breakdown voltage semiconductor device further comprises a first TID improvement region formed below the isolation region, a second TID improvement region formed, within the body region, adjacent to a side wall of the isolation region, and a third TID improvement region formed, within the body region, below the isolation region.
